(19) United States
(12) Patent Application Publication
(10) Pub. No.: US 2026/0305079 A1
(43) Pub. Date: Oct. 1, 2026

(54) DISPLAY DEVICE AND ELECTRONIC DEVICE INCLUDING THE SAME

(71) Applicant: Samsung Display Co., Ltd., Yongin-Si (KR)

(72) Inventors: EUNJIN KWAK, Yongin-si (KR); SOOYOUN KIM, Yongin-si (KR); HYUNHO KIM, Yongin-si (KR); HYEONBUM LEE, Yongin-si (KR)

(21) Appl. No.: 19/417,331

(22) Filed: Dec. 12, 2025

(30) Foreign Application Priority Data
Mar. 26, 2025 (KR) 10-2025-0038906

(51) Int. Cl. H10K 59/122; H10K 59/38; H10K 59/80

(52) U.S. Cl. CPC H10K 59/122; H10K 59/38; H10K 59/873

(57) ABSTRACT

A display device includes a base substrate, a display element layer, a circuit element layer, and a color control layer. The display element layer is disposed on the substrate and includes a light-emitting layer, a pixel electrode disposed between the light-emitting layer and the base substrate, an opposing electrode facing the pixel electrode across the light-emitting layer, and a pixel defining layer not overlapping a portion of the pixel electrode. The circuit element layer is disposed between the display element layer and the base substrate. The color control layer is disposed on the display element layer and includes amorphous silicon. The pixel electrode includes a first upper surface recessed with respect to the light-emitting layer and not overlapping the pixel defining layer and a second upper surface extending from the first upper surface and overlapping the pixel defining layer. The color control layer overlaps the second upper surface.

This application claims priority to Korean Patent Application No. 10-2025-0038906, filed on Mar. 26, 2025, and all the benefits accruing therefrom under 35 U.S.C. §119, the content of which is incorporated herein in its entirety by reference.

### BACKGROUND

### 1. Field

The present disclosure relates to a display device and an electronic device including the same, and more particularly, to a display device including a display element and an electronic device including the same.

### 2. Description of the Related Art

A display device presents various images on a display screen to provide information to a user. Typically, the display device displays information within a designated screen area defined as a display region. The display device can emit light of various colors to the outside through a display element that includes a light-emitting material.

When displaying images, it is necessary to minimize the reflection of external light. Due to such reflection, even though the display device outputs images to the outside, the images may not be clearly visible. Materials with high reflectance, such as metal electrodes inside the

display device, may reflect external light and cause the display screen to appear like a mirror. To prevent this, the display device includes an anti-reflection layer to reduce the reflection of external light. Under such structural configurations, there is a growing demand for improving the optical quality of the display device.

### SUMMARY

The present disclosure provides a display device that improves the color of the display surface when in a non-driving state. The present disclosure provides a display device that improves image quality degradation caused by changes in viewing angle.

According to an embodiment of the present disclosure, a display device includes a base substrate, a display element layer, a circuit element layer, and a color control layer. The display element layer is disposed on the substrate and includes a light-emitting layer, a pixel electrode disposed between the light-emitting layer and the base substrate, an opposing electrode disposed to face the pixel electrode across the light-emitting layer, and a pixel defining layer not overlapping a portion of the pixel electrode and exposing a portion of the pixel electrode. The circuit element layer is disposed between the base substrate and the display element layer and includes a pixel circuit electrically connected to the pixel electrode. The color control layer is disposed on the display element layer and includes amorphous silicon. The pixel electrode is recessed with respect to the light-emitting layer and includes a first upper surface not overlapping the pixel defining layer and a second upper surface extending from the first upper surface and overlapping the pixel defining layer. The color control layer overlaps the second upper surface.

In an example, the display device may further include an encapsulation layer disposed on the circuit element layer and the display element layer and covering the display element layer and a color filter disposed on the encapsulation layer and overlapping the light-emitting layer. The color filter may include a red color filter configured to transmit light corresponding to red, and the red color filter may overlap the pixel defining layer.

In an example, the display device may further include a transparent coating layer disposed on the encapsulation layer and the color filter and covering the color filter, and the color control layer may be disposed on the transparent coating layer.

In another example, the display device may further include a transparent coating layer disposed on the encapsulation layer and the color filter and covering the color filter, and the color control layer may be disposed between the encapsulation layer and the transparent coating layer.

In another example, the color control layer may be disposed on the color filter.

In another example, the display device may further include an encapsulation layer disposed on the circuit element layer and the display element layer and covering the display element layer and a light-blocking layer disposed on the encapsulation layer and overlapping the pixel defining layer. The color control layer may be disposed on the light-blocking layer.

In another example, the display device may further include an encapsulation layer disposed on the circuit element layer and the display element layer and covering the display element layer and an input sensing unit disposed on the encapsulation layer. The color control layer may be disposed between the encapsulation layer and the input sensing unit.

In another example, the encapsulation layer may further include an encapsulation layer disposed on the circuit element layer and the display element layer, covering the display element layer, and including an organic layer and an inorganic layer that are stacked, and the color control layer may be disposed between the organic layer and the inorganic layer.

In another example, the color control layer may further overlap the first upper surface.

In another example, the color control layer may not overlap the first upper surface.

In another example, within light-emitting regions defined by the pixel defining layer, the color control layer may not overlap a light-emitting region configured to emit light of a target color and may overlap a light-emitting region configured to emit light of a color different from the target color.

In another example, within light-emitting regions defined by the pixel defining layer, the color control layer may overlap a light-emitting region configured to emit light of a target color and may not overlap a light-emitting region configured to emit light of a color different from the target color.

According to another embodiment of the present disclosure and a display device includes a base substrate, a display element layer, a circuit element layer, and a color control layer. The display element layer is disposed on the substrate and includes a light-emitting layer, a pixel electrode disposed between the light-emitting layer and the base substrate and having a recessed upper surface with respect to the light-emitting layer, and an opposing electrode facing the pixel electrode across the light-emitting layer. The circuit element layer is disposed between the base substrate and the display element layer and includes a pixel circuit electrically connected to the pixel electrode. The color control layer is disposed on the display element layer and has a transmittance for light corresponding to yellow that is higher than a transmittance for light corresponding to blue.

In an example, the color control layer may include amorphous silicon.

In an example, the color control layer may have a maximum light transmittance in a wavelength range between 570 nm and 590 nm.

In an example, the color control layer may have a minimum light reflectance in a wavelength range between 570 nm and 590 nm.

According to yet another embodiment of the present disclosure, a display device includes a base substrate, a display element layer, a circuit element layer, and a color control layer. The display element layer is disposed on the substrate and includes a light-emitting layer, a pixel electrode disposed between the light-emitting layer and the base substrate, and an opposing electrode facing the pixel electrode across the light-emitting layer. The circuit element layer is disposed between the display element layer and the base substrate and includes a pixel circuit electrically connected to the pixel electrode. The color control layer is disposed on the display element layer and includes amorphous silicon. When a voltage between the pixel electrode and the opposing electrode is lower than a driving voltage of the light-emitting layer, the reflectance for light corresponding to blue in the display element layer is higher than the reflectance for light corresponding to yellow.

In an example, the pixel electrode may have a recessed upper surface with respect to the light-emitting layer.

In an example, when a voltage between the pixel electrode and the opposing electrode is lower than a driving voltage of the light-emitting layer, the reflectance for light corresponding to green in the display element layer may be higher than the reflectance for light corresponding to red.

In an example, the color control layer may overlap at least a portion of the pixel electrode in a direction normal to the surface of the pixel electrode.

According to an embodiment of the present disclosure, by providing a color control layer on the display element layer, the color of the display surface in a non-driving state can be improved.

Additionally, according to an embodiment of the present disclosure, by forming the pixel electrode with a concave shape, image quality with respect to viewing angle can be improved.

Furthermore, according to an embodiment of the present disclosure, by patterning the color control layer, degradation in image quality can be prevented.

### BRIEF DESCRIPTION OF THE DRAWINGS

These and other features will become apparent and more readily appreciated from the following description of the embodiments, taken in conjunction with the accompanying drawings.

FIG. 1 is an exploded perspective view illustrating a display device according to an embodiment of the present disclosure.

FIG. 2 is an exploded perspective view illustrating an embodiment of an electronic panel shown in FIG. 1.

FIG. 3 is an equivalent circuit diagram of an embodiment of a pixel shown in FIG. 2.

FIG. 4 is a timing diagram illustrating the operation of the pixel shown in FIG. 3.

FIG. 5 is a cross-sectional view illustrating an embodiment of the display unit shown in FIG. 2.

FIG. 6 is a cross-sectional view illustrating an embodiment of the input sensing unit shown in FIG. 2.

FIG. 7 is a cross-sectional view illustrating a pixel according to an embodiment of the present disclosure.

FIG. 8 is a graph illustrating improvement in reflectance color of the display device according to an embodiment of the present disclosure.

FIGS. 9A, 9B, 9C, 9D, 9E, 9F, 9G and 9H are plan views illustrating embodiments of the color control layer shown in FIG. 7.

FIG. 10 is a cross-sectional view of a pixel according to an embodiment of the present disclosure.

FIG. 11 is another cross-sectional view illustrating a pixel according to an embodiment of the present disclosure.

FIG. 12 is another cross-sectional view illustrating a pixel according to an embodiment of the present disclosure.

FIG. 13 is another cross-sectional view illustrating a pixel according to an embodiment of the present disclosure.

FIG. 14 is another exemplary cross-sectional view illustrating a pixel according to an embodiment of the present disclosure.

FIG. 15 is another cross-sectional view illustrating a pixel according to an embodiment of the present disclosure.

FIG. 16 is another exemplary cross-sectional view illustrating a pixel according to an embodiment of the present disclosure.

FIG. 17 is another exemplary cross-sectional view illustrating a pixel according to an embodiment of the present disclosure.

FIG. 18 is a block diagram illustrating an electronic device according to an embodiment.

FIG. 19 is a schematic diagram illustrating various electronic devices according to various embodiments.

### DETAILED DESCRIPTION

The present disclosure now will be described more fully hereinafter with reference to the accompanying drawings, in which various embodiments are shown. The present disclosure may, however, be embodied in many different forms, and should not be construed as limited to the embodiments set forth herein. Rather, these embodiments are provided so that this disclosure will be thorough and complete, and will fully convey the scope of the disclosure to those skilled in the art.

In the accompanying drawings, the ratios and dimensions of elements may be exaggerated for clarity and ease of understanding. As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.

Expressions such as “comprise” and “include” are intended to specify the presence of features, integers, steps, operations, elements, components, or combinations thereof stated in the specification, and shall not be construed to preclude any possibility of presence or addition of one or more other features, integers, steps, operations, elements, components, or combinations thereof.

In the following description, first to third directions DR1, DR2, DR3 are defined to describe a display device according to embodiments of the disclosure. The display device includes

an electronic panel (or a display panel), which is formed to include pixels on a plane defined by a first direction DR1 and a second direction DR2. A third direction DR3 is defined as a thickness direction of the display device, and the first to third directions DR1 - DR3 may be orthogonal to each other.

In describing the color properties of the display device according to embodiments of the present disclosure, terms such as red, yellow, green, and blue are used. These color terms are not limited to specific wavelengths within the visible spectrum but shall be understood as relative concepts including typical wavelength ranges associated with the respective colors.

For example, red may correspond to a wavelength range of approximately 630 nm to 700 nm, yellow to approximately 570 nm to 590 nm, green to approximately 520 nm to 570 nm, and blue to approximately 450 nm to 500 nm. However, when comparing a first color and a second color among these four, if the wavelength of interest does not fall within the ranges of a third or fourth color even if it is outside the wavelength ranges of the first and second colors, but is clearly closer to the second color compared to the first, it is understood as belonging to the second color. For instance, in comparing yellow and blue, a wavelength shorter than the green range (e.g., 510 nm or 440 nm) may be considered part of blue, while a wavelength shorter than red but longer than green (e.g., 600 nm) may be considered part of yellow.

In the below description, terms such as “reddish,” “yellowish,” “greenish,” and “bluish” are used to describe color tendencies of the display device in various states. These terms relate to directional tendencies in color space as defined by the a* and b* axes of the CIE (Commission Internationale de l'Eclairage) color coordinate system. “Reddish” refers to a positive, relatively big, or increasing direction along the a* axis. “Yellowish” refers to a positive, relatively big, or increasing direction along the b* axis. “Greenish” refers to a negative, relatively small, or decreasing direction along the a* axis. “Bluish” refers to a negative, relatively small, or decreasing direction along the b* axis.

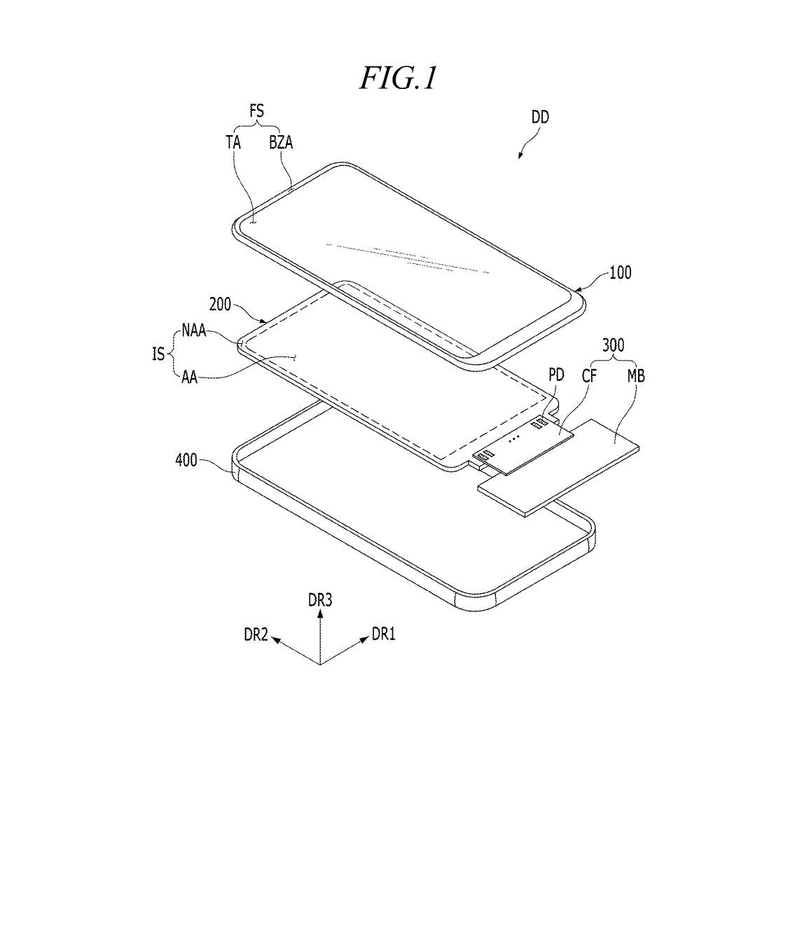

FIG. 1 is an exploded perspective view illustrating a display device according to an embodiment of the present disclosure. Referring to FIG. 1, a display device DD includes a window 100, an electronic panel 200, a circuit board 300, and a case 400. It shall be appreciated that the shape of the display device DD shown in FIG. 1 is illustrative. The display device DD may be applied to various electronic devices such as tablet PCs, smartphones, personal digital assistants (PDAs), portable multimedia players (PMPs), gaming devices, televisions, personal computers, notebook computers, and kiosks.

The window 100 is disposed on the electronic panel 200 and covers a front surface IS of the electronic panel 200. The window 100 may include an optically transparent insulating material. For example, the window 100 may include glass or plastic. The window 100 may have a multilayer or single-layer structure. For instance, the window 100 may have a laminated structure of multiple plastic films bonded with adhesive or a laminated structure of a glass substrate and a plastic film bonded with adhesive.

The window 100 includes a front surface FS that is exposed externally. A front surface FS of an electronic device EA may be substantially defined by the front surface FS of the window 100. The front surface FS may be defined parallel to a plane defined by a first direction DR1 and a second direction DR2. The front surface FS includes a transmission area TA and a bezel area BZA adjacent to the transmission area TA.

The transmission area TA may be an optically transparent region and may have a rectangular shape aligned with the first direction DR1 and the second direction DR2. However, it is not limited to such a shape and may have various other shapes. The transmission area TA may correspond in shape to an active area AA of the electronic panel 200, as described below. An image output from the electronic panel 200 may be viewed externally through the transmission area TA.

The bezel area BZA may be a region with relatively lower light transmittance than the transmission area TA. The bezel area BZA is adjacent to and may surround the transmission area TA. Nonetheless, the bezel area BZA is not limited to this configuration and may be disposed adjacent to only one side of the transmission area TA or may be omitted. The bezel area BZA defines the shape of the transmission area TA.

The bezel area BZA may cover a peripheral area NAA of the electronic panel 200 to prevent the peripheral area NAA from being visible externally. The bezel area BZA may have a predetermined color. If the window 100 is provided as a glass or plastic substrate, the bezel area BZA may be a color layer printed or deposited on one surface of the glass or plastic substrate, or formed by coloring a region of the glass or plastic substrate.

The electronic panel 200 is configured to display images and detect external input. The external input may include user touch or proximity and may encompass various input types such as body contact, light, heat, or pressure. The electronic panel 200 includes the active area AA and the peripheral area NAA one the plane.

The active area AA may be a region activated in response to electrical signals. For example, the active area AA may be a region where images are displayed and at the same time external input is detected. However, the disclosure is not limited to this description, and within the active area AA, an image display region and an input detection region may differ. The active area AA may have a shape corresponding to the transmission area TA and may at least partially overlap the transmission area TA.

The peripheral area NAA is adjacent to and may surround the active area AA. Nonetheless, the peripheral area NAA is not limited to this configuration, and the peripheral area NAA may be adjacent to only part of an edge of the active area AA. Various signal lines, pads PD, or electronic components configured to supply electrical signals to the active area AA may be disposed in the peripheral area NAA. The peripheral area NAA may be covered by the bezel area BZA to prevent it from being visible from the outside.

The circuit board 300 is connected to the electronic panel 200. For example, to reduce the size of the bezel area BZA, the circuit board 300 may be located on a rear surface of the electronic panel 200. For this purpose, a portion of the electronic panel 200 may be bent about a bending axis parallel to the first direction DR1. The circuit board 300 may include a flexible substrate CF and a main board MB.

The flexible substrate CF may include an insulating film and conductive wirings mounted on the insulating film. The conductive wirings may be connected to the pads PD to electrically connect the circuit board 300 and the electronic panel 200. The flexible substrate CF may be omitted, and the main board MB may be directly connected to the electronic panel 200. On the other hand, the electronic panel 200 may remain unbent, and the flexible substrate CF may be bent about a bending axis parallel to the first direction DR1 so that the main board MB is located on a rear side of the electronic panel 200.

The main board MB may include signal lines and electronic components (not shown). The electronic components may be connected to the signal lines and electrically connected to the electronic panel 200. These electronic components are configured to generate or process various electrical signals, such as signals for image generation or input detection. Multiple main boards MB may be provided depending on signals required to be generated or processed.

An external case 400 is disposed below the electronic panel 200. The external case 400 may include a material with greater rigidity than the electronic panel 200. For example, the external case 400 may include a frame or plate formed of glass, plastic, or metal. The external case 400 provides a predetermined receiving space. The electronic panel 200 and the circuit board 300 may be housed within the receiving space to be protected from external impact. The window 100 and the external case 400 may be joined to form the exterior of the electronic device EA.

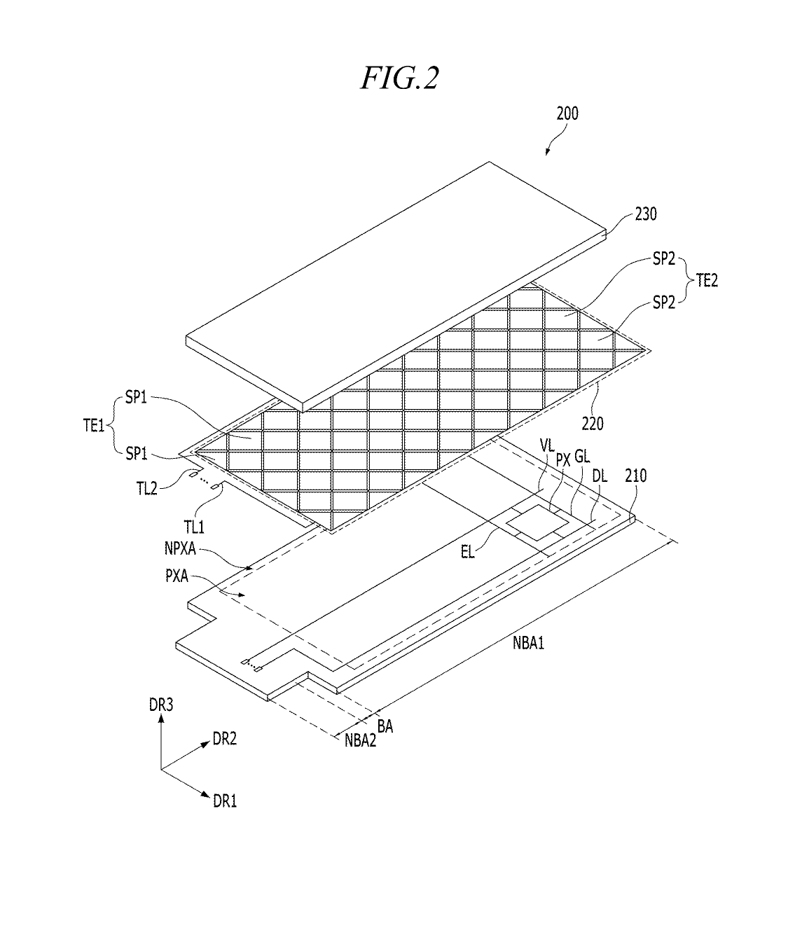

FIG. 2 is an exploded perspective view illustrating an embodiment of the electronic panel shown in FIG. 1. Referring to FIG. 2 and using the same reference symbols and numerals as in FIG. 1 for convenience of explanation, the electronic panel 200 includes a display unit 210, an input sensing unit 220, and an optical functional unit 230.

The display unit 210 may be configured to generate and display images in an active area AA. The display unit 210 may be, for example, an organic light-emitting display panel. The display unit 210 includes a pixel region PXA in which pixels PX are arranged on a plane and a non-pixel region NPXA adjacent to the pixel region PXA. In the non-pixel region NPXA, pixels PX are not provided; instead, peripheral structures such as signal lines and insulating patterns may be formed. Although not limited thereto, the pixel region PXA and the non-pixel region NPXA may correspond, respectively, to the transmission area TA and the bezel area BZA.

The display unit 210 may include a first non-bending region NBA1, a bending region BA, and a second non-bending region NBA2. The bending region BA may extend in the second direction DR2 from the first non-bending region NBA1. The second non-bending region NBA2 may extend in the second direction DR2 from the bending region BA. In the bent state, the second non-bending region NBA2 faces the first non-bending region NBA1. The bending region BA has a predetermined curvature when bent.

The display unit 210 includes a plurality of signal lines GL, DL, VL, EL and pixels PX. Each pixel PX emits light in response to electrical signals to form an image. A plurality of pixels PX may be provided, each connected to a corresponding signal line GL, DL, VL, EL. The pixels PX and the signal lines GL, DL, VL, EL may be disposed on a substrate of the display unit 210. The pixels PX may be disposed in the first non-bending region NBA1.

The signal lines GL, DL, VL, EL may include a gate line GL, a data line DL, a power line VL, and a light emission control line EL, each carrying a different type of electrical signal. Pads PD shown in FIG. 1 connected to the signal lines GL, DL, VL, EL may be disposed in the non-pixel region NPXA.

The gate line GL extends along the first direction DR1. The gate line GL is provided in plurality, which are arranged at intervals along the second direction DR2. Although not illustrated, the display unit 210 may further include a gate driving circuit (not shown) configured for supplying gate signals to the gate lines GL. The gate driving circuit (not shown) may be located in the non-pixel region NPXA adjacent to the pixel region PXA in the first direction DR1. The gate driving circuit may be electrically connected to the circuit board 300 via the pads PD. However, the disclosure is not limited to this configuration, and the gate driving circuit may also be mounted on a separate circuit board included in the circuit board 300.

The data line DL extends in the second direction DR2 and is electrically insulated from the gate lines GL. The data line DL is provided in plurality, which may be arranged at intervals along the first direction DR1. The data lines DL are configured to provide data signals to the pixels PX and may be electrically connected to the circuit board 300 through the pads PD.

The light emission control line EL extends in the first direction DR1 and is electrically insulated from the data line DL and gate line GL. The light emission control line EL is provided in plurality, which may be arranged at intervals along the second direction DR2. Although not depicted, the display unit 210 may further include a light emission driving circuit (not shown) for supplying light emission control signals to the light emission control lines EL. The light emission driving circuit may be disposed in the non-pixel region NPXA adjacent to the pixel region PXA in the first direction DR1 and may be electrically connected to the circuit board 300 via the pads PD. However, the disclosure is not limited to this configuration, and the light emission driving circuit may be mounted on a separate circuit board included in the circuit board 300.

The power line VL extends in the second direction DR2 and may be electrically insulated from the gate lines GL, data lines DL, and light emission control lines EL. The power line VL may be provided in plurality, which may be arranged at intervals along the first direction DR1. The power lines VL are configured to supply power signals to the pixels PX and may be electrically connected to the circuit board 300 via the pads PD.

The input sensing unit 220 is disposed on the display unit 210 and configured to detect external input to obtain position or intensity information of an external input TC. The input sensing unit 220 may include a plurality of sensing electrodes TE1, TE2, and a plurality of sensing lines TL1, TL2.

The sensing electrodes TE1, TE2 are disposed in the active area AA and may overlap the pixel region PXA. The sensing electrodes TE1, TE2 may include a first sensing electrode TE1 and a second sensing electrode TE2 that receive different electrical signals. The input sensing unit 220 may be configured to detect changes in capacitance between the first sensing electrode TE1 and the second sensing electrode TE2 to determine information about the external input.

The first sensing electrode TE1 extends in the second direction DR2. The first sensing electrode TE1 may be provided in plurality, which may be arranged at intervals along the first direction DR1. The first sensing electrode TE1 may include a plurality of first sensing patterns SP1 arranged along the first direction DR1 and electrically connected to each other.

The second sensing electrode TE2 extends in the first direction DR1. The second sensing electrode TE2 may be provided in plurality, which may be arranged at intervals along the first direction DR1. The second sensing electrode TE2 may include a plurality of second sensing patterns SP2 arranged along the first direction DR1 and electrically connected to each other.

The sensing lines TL1, TL2 are disposed in the peripheral area NAA and may overlap the non-pixel region NPXA. The sensing lines TL1, TL2 include a first sensing line TL1 and a second sensing line TL2. The first sensing line TL1 (or the second sensing line TL2) may be configured to transfer an electrical signal supplied from outside through the circuit board 300 to the first sensing electrode TE1 (or the second sensing electrode TE2). The second sensing line TL2 (or the first sensing line TL1) may be configured to transfer a sensing signal received from the second sensing electrode TE2 (or the first sensing electrode TE1) to the circuit board 300.

The optical functional unit 230 is disposed on the display unit 210 and the input sensing unit 220. The optical functional unit 230 may include functional layers that allow an image output by the electronic panel 200 to be clearly visible to a user. The optical functional unit 230 may be configured to reduce reflectance of external light. To this end, the optical functional unit 230 may include a color filter and a light-blocking layer, which will be described in further detail below. Additionally, the optical functional unit 230 may improve reflectance color appearance when the display unit 210 is not driven. To this end, the optical functional unit 230 may include a color control layer, which will be described later. The optical functional unit 230 may be attached to the window 100.

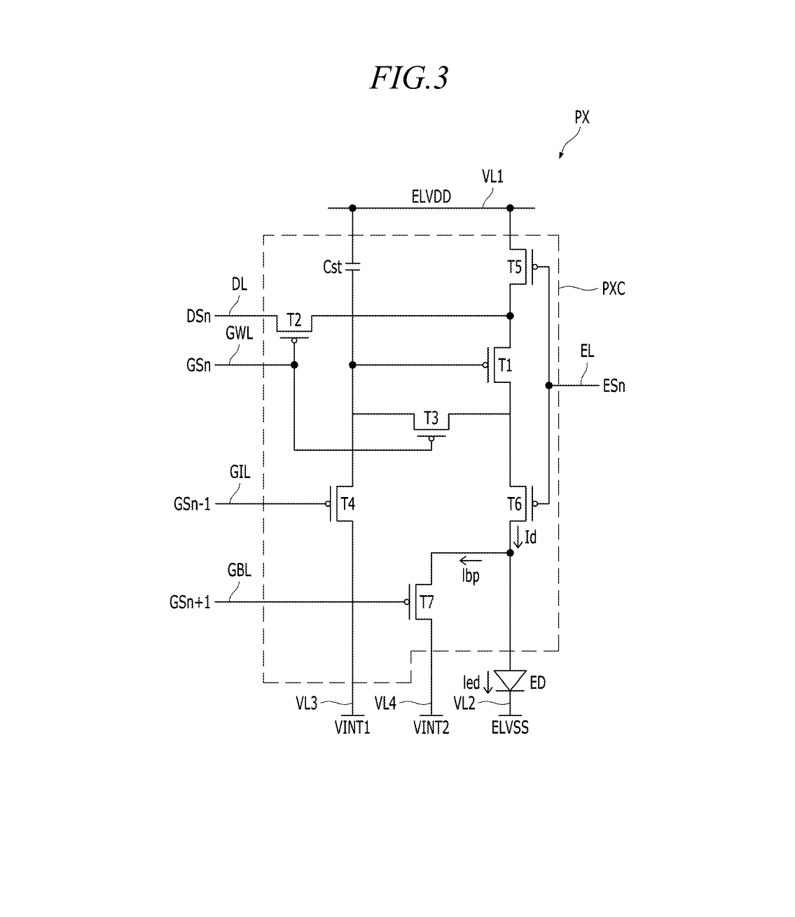

FIG. 3 is an equivalent circuit diagram of an embodiment of a pixel shown in FIG. 2. Referring to FIG. 3, the pixel PX is electrically connected to power lines VL1, VL2, VL3, VL4, data line DL, gate lines GWL, GIL, GBL, and light emission control lines EL.

The pixel PX is configured to receive, respectively, a first driving voltage ELVDD, a second driving voltage ELVSS, a first initialization voltage VINT1, and a second initialization voltage VINT2 through the power lines VL1, VL2, VL3, L4, which may be provided using voltages generated by a power management circuit or the like included in or connected to the circuit board 300 of the display device DD shown in FIG. 1.

The pixel PX includes a pixel circuit PXC and a light-emitting diode ED. The pixel circuit PXC includes first to seventh transistors T1 - T7 and one capacitor Cst. Each of the first to seventh transistors T1 - T7 may be a P-type transistor having a low-temperature polycrystalline silicon (LTPS) semiconductor layer, but this is not limiting. The transistors may alternatively be N-type transistors having an oxide semiconductor as the semiconductor layer. Furthermore, at least one of the first to seventh transistors T1 - T7 may be an N-type transistor while the others are P-type transistors. The circuit configuration and number of transistors in the pixel PX according to the present disclosure are merely exemplary and not limited to FIG. 3; the structure of the pixel circuit PXC may be implemented in various modifications.

The first transistor T1 includes a first electrode connected to a first driving voltage line VL1 via the fifth transistor T5, a second electrode electrically connected to the anode of the light-emitting diode ED via the sixth transistor T6, and a gate electrode connected to one end of the capacitor Cst. The first transistor T1 is configured to receive a data signal DSn from the data line DL according to the switching operation of the second transistor T2 and supply a driving current Id to the light-emitting diode ED.

The second transistor T2 includes a first electrode connected to the data line DL, a second electrode connected to the first electrode of the first transistor T1, and a gate electrode connected to a second gate line GWL. The second transistor T2 is configured to be turned on in response to a second gate signal GSn provided through the second gate line GWL and transfer the data signal DSn from the data line DL to the first electrode of the first transistor T1.

The third transistor T3 includes a first electrode connected to the gate electrode of the first transistor T1, a second electrode connected to the second electrode of the first transistor T1, and a gate electrode connected to the second gate line GWL. The third transistor T3 is configured to be turned on according to the second gate signal GSn received through the second gate line GWL and connect the gate electrode with the second electrode of the first transistor T1 to form a diode connection for the first transistor T1.

The fourth transistor T4 includes a first electrode connected to the gate electrode of the first transistor T1, a second electrode connected to a third voltage line VL3 to which the first initialization voltage VINT1 is transferred, and a gate electrode connected to the first gate line GIL. The fourth transistor T4 is configured to be turned on according to a first gate signal GSn−1 received through the first gate line GIL to transfer the initialization voltage VINT1 to the gate electrode of the first transistor T1, thereby performing an initialization operation of the gate electrode.

The fifth transistor T5 includes a first electrode connected to the first driving voltage line VL1, a second electrode connected to the first electrode of the first transistor T1, and a gate electrode connected to the light emission control line EL. The sixth transistor T6 includes a first electrode connected to the second electrode of the first transistor T1, a second electrode connected to the anode of the light-emitting diode ED, and a gate electrode connected to the light emission control line EL. The fifth transistor T5 and the sixth transistor T6 are configured to be simultaneously turned on according to a light emission control signal ESn received through the light emission control line EL. The first driving voltage ELVDD applied through the turned-on fifth transistor T5 may be compensated through the first transistor T1 and transferred to the light-emitting diode ED.

The seventh transistor T7 includes a first electrode connected to a fourth voltage line VL4 to which the second initialization voltage VINT2 is transferred, a second electrode connected to the second electrode of the sixth transistor T6, and a gate electrode connected to a third gate line GBL. The seventh transistor T7 is configured to be turned on according to a third gate signal GSn+1 received through the third gate line GBL. The second initialization voltage VINT2 applied through the turned-on seventh transistor T7 may initialize the anode of the light-emitting diode ED.

One end of the capacitor Cst is connected to the gate electrode of the transistor T1, as described above, and the other end is connected to the first driving voltage line VL1. The cathode of the light-emitting diode ED may be connected to a second driving voltage line VL2 that transfers the second driving voltage ELVSS.

The light-emitting diode ED may include a light-emitting material such as an organic light-emitting material, inorganic light-emitting material, quantum dot, or quantum rod. The light-emitting diode ED may be configured to emit light based on a light-emission current Ied.

FIG. 4 is a timing diagram illustrating the operation of the pixel shown in FIG. 3. FIG. 4 will be described using the same reference symbols used in FIG. 3. Referring to FIG. 4, the pixel PX operates in four intervals for a light emission operation: a first interval p1, a second interval p2, a third interval p3, and a fourth interval p4.

In the first interval p1, a node for programming the pixel PX is initialized. During the first interval p1, a first gate signal GSn-1 at a low level is supplied through the first gate line GIL. Based on the low-level first gate signal GSn-1, the fourth transistor T4 is turned on, and the first initialization voltage VINT1 is transferred to the gate electrode of the first transistor T1 through the fourth transistor T4, thereby initializing the first transistor T1.

In the second interval p2, the pixel PXij is programmed. When the second gate signal GSn at a low level is supplied through the second gate line GWL during the second interval p2, the third transistor T3 is turned on. The first transistor T1 is diode-connected and forward-biased by the turned-on third transistor T3. Also, the second transistor T2 is turned on by the low-level second gate signal GSn. As a result, a compensation voltage (DSn − Vth), which is a data signal DSn supplied from the data line DL reduced by the threshold voltage Vth of the first transistor T1, is applied to the gate electrode of the first transistor T1. This gate voltage shall be understood as the compensation voltage. The first driving voltage ELVDD and the compensation voltage are applied to either end of the capacitor Cst, and a charge corresponding to the voltage difference may be stored in the capacitor Cst.

In the third interval p3, the anode of the light-emitting diode ED is initialized. The seventh transistor T7 is turned on by receiving a low-level third gate signal GSn+1 through the third gate line GBL. Even if a minimum current of the first transistor T1 for displaying a black image flows as a driving current, the black image will not be properly displayed if the light-emitting diode ED emits light. Accordingly, the seventh transistor T7 can divert a portion of the minimum current of the first transistor T1 into an alternative current path as a bypass current Ibp, rather than through the light-emitting diode. The light-emission current Ied of the light-emitting diode ED, reduced by the bypass current Ibp from the driving current Id, is minimized to a level sufficient to represent a black image effectively, thereby enhancing the contrast ratio.

In the fourth interval p4, the light-emitting diode ED emits light based on the programmed data signal DSn. A light emission control signal ESn supplied from the light emission control line EL changes from a high level to a low level. The low-level light emission control signal ESn turns on the fifth and sixth transistors T5, T6. Consequently, a driving current Id is generated in accordance with the voltage difference between the gate electrode of the first transistor T1 and the first driving voltage ELVDD. This driving current Id is supplied to the light-emitting diode ED through the sixth transistor T6, thereby causing a light-emission current Ied to flow in the light-emitting diode ED.

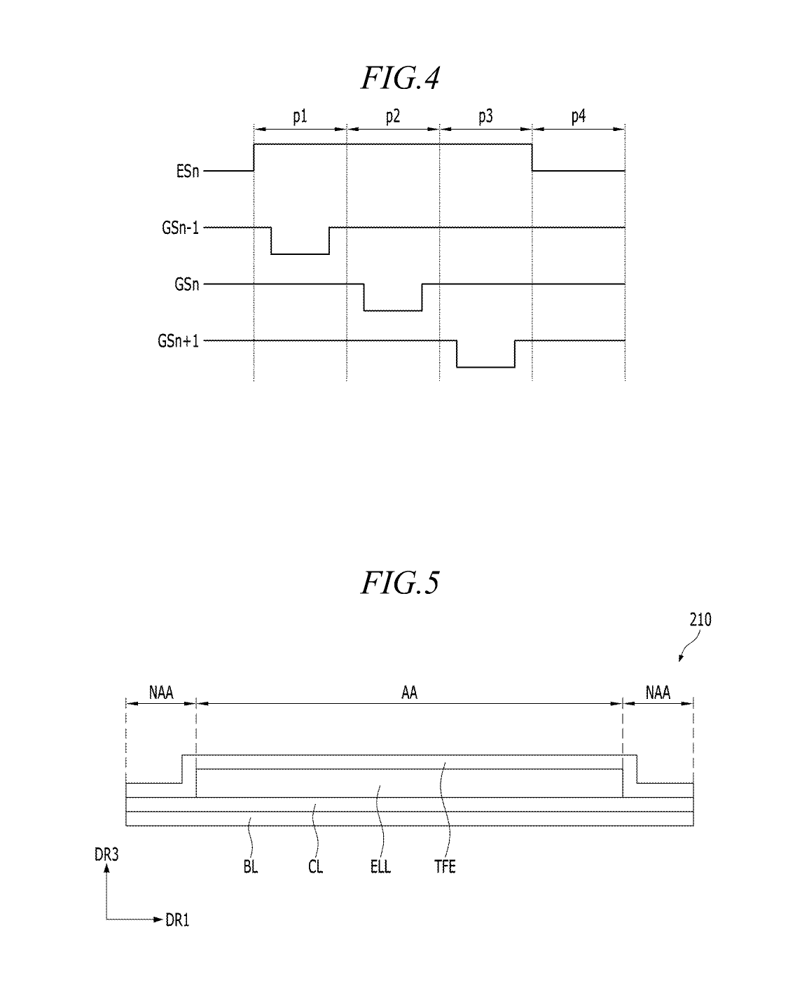

FIG. 5 is a cross-sectional view illustrating an embodiment of the display unit shown in FIG. 2. Referring to FIG. 5, the display unit 210 includes a base substrate BL, a circuit element layer CL, a display element layer ELL, and an encapsulation layer TFE. For convenience of explanation, FIG. 5 will be described using the same reference symbols as in FIG. 2.

The base substrate BL may be formed of various materials such as glass, metal, or plastic and may include a transparent and flexible substrate. The base substrate BL may include a substrate having a substantially uniform refractive index in the wavelength range of visible light.

The circuit element layer CL is disposed on the base substrate BL and may include at least one insulating layer and a circuit element. The circuit element layer CL includes the plurality of transistors described above. The insulating layer of the circuit element layer CL may include at least one inorganic layer or at least one organic layer. The circuit element may include various signal lines GL, DL, PL, EL and the pixel circuit PXC described with reference to FIG. 3.

The display element layer ELL is disposed on the circuit element layer CL. The display element layer ELL may include a plurality of light-emitting diodes. One light-emitting diode corresponds to one pixel PX. The display element layer ELL may include organic light-emitting diodes as the light-emitting diodes. The display element layer ELL may also include a pixel defining layer, for example, an organic material. The display element layer ELL may overlap an active area AA and may not overlap a peripheral area NAA. Here, the active area AA corresponds to the pixel region PXA in FIG. 2.

The encapsulation layer TFE is disposed on the circuit element layer CL and the display element layer ELL and covers the display element layer ELL. The encapsulation layer TFE may include a plurality of thin films and may include at least one inorganic layer or at least one organic layer in a stacked structure. The encapsulation layer TFE is configured to protect the display element layer ELL from moisture, oxygen, dust, and the like. The encapsulation layer TFE may be disposed on the display element layer ELL in the active area AA and may be disposed on the circuit element layer CL in the peripheral area NAA.

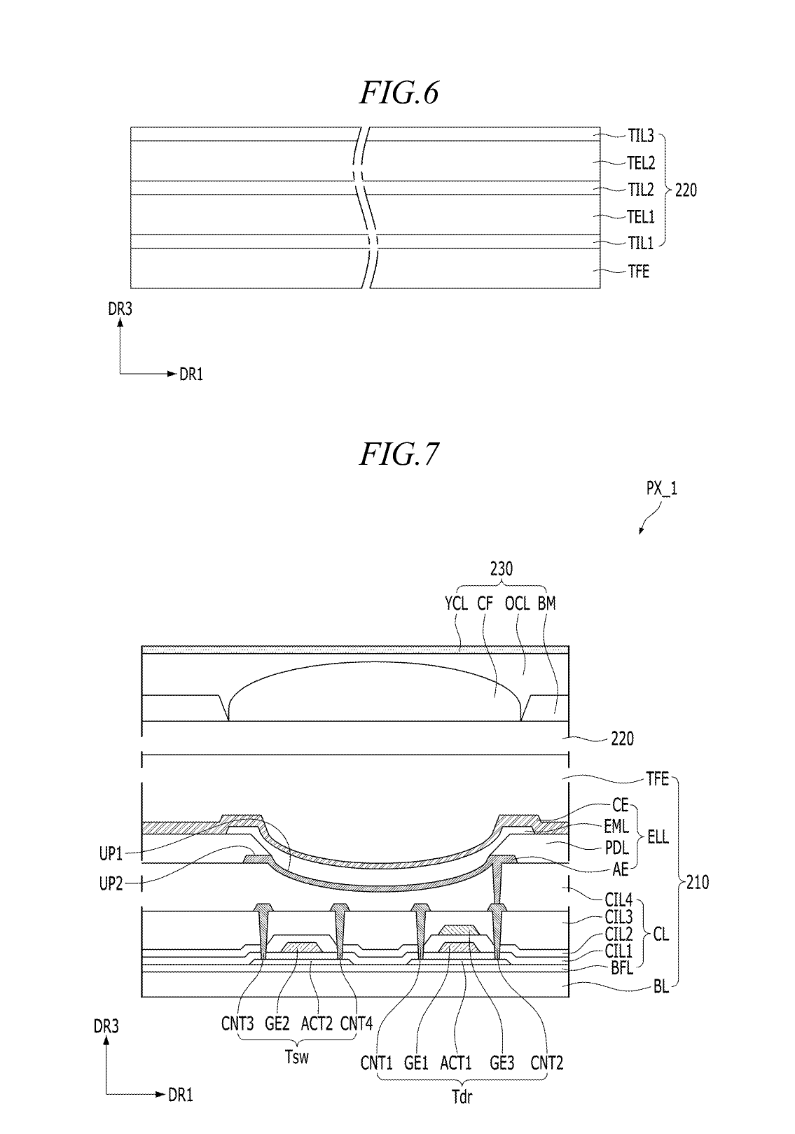

FIG. 6 is a cross-sectional view illustrating an embodiment of the input sensing unit shown in FIG. 2. Referring to FIG. 6, the input sensing unit 220 may include a first insulating layer TIL1, a first conductive layer TEL1, a second insulating layer TIL2, a second conductive layer TEL2, and a third insulating layer TIL3. The first insulating layer TIL1 may be directly disposed on the above-described encapsulation layer TFE. In one example, the first insulating layer TIL1 may be omitted. Each of the first conductive layer TEL1 and the second conductive layer TEL2 includes a plurality of conductive patterns, which may correspond to the first sensing patterns SP1 and the second sensing patterns SP2 described in FIG. 2.

Each of the first conductive layer TEL1 and the second conductive layer TEL2 may have a single-layer structure or a multilayer structure stacked along the third direction DR3. The multilayer structure of the conductive layer may include at least two of transparent conductive layers and metal layers. The multilayer conductive layer may include metal layers composed of different metals. The transparent conductive layer may include indium tin oxide (ITO), indium zinc oxide (IZO), zinc oxide (ZnO), indium tin zinc oxide (ITZO), PEDOT, metal nanowires, or graphene. The metal layer may include molybdenum, silver, titanium, copper, aluminum, or alloys thereof. In one example, each of the first conductive layer TEL1 and the second conductive layer TEL2 may have a three-layer metal structure, such as a titanium/aluminum/titanium stacked structure.

Each of the first insulating layer TIL1, the second insulating layer TIL2, and the third insulating layer TIL3 may include an inorganic film or an organic film. The inorganic film may include at least one of aluminum oxide, titanium oxide, silicon oxide, silicon oxynitride, zirconium oxide, and hafnium oxide. The organic film may include at least one of acrylic resin, methacrylic resin, polyisoprene, vinyl resin, epoxy resin, urethane resin, cellulose-based resin, siloxane-based resin, polyimide resin, polyamide resin, and perylene-based resin.

FIG. 7 is a cross-sectional view illustrating a pixel PX_1 according to an embodiment of the present disclosure. Referring to FIG. 7, the pixel PX_1 includes portions of the display unit 210, the input sensing unit 220, and the optical functional unit 230. The display unit 210, the input sensing unit 220, and the optical functional unit 230 are part of the electronic panel 200 described above. For convenience of explanation, a single cross-sectional view of the pixel PX_1 is shown, though pixels PX are arranged in a two-dimensional array and the structure shown with the cross-sectional view in FIG. 7 may be repeated along the first direction DR1. Furthermore, it shall be appreciated that the cross-sectional view of the pixel PX_1 is simplified for convenience of explanation.

The display unit 210 includes a base substrate BL, a circuit element layer CL, a display element layer ELL, and an encapsulation layer TFE. As previously described with reference to FIG. 5, the base substrate BL may be formed of various materials such as glass, metal, or plastic.

The circuit element layer CL includes a buffer layer BFL, insulating layers CIL1 - CIL4, active patterns ACT1, ACT2, gate patterns GE1 - GE3, and input/output patterns CNT1 - CNT4. Based on the stacked structure shown in FIG. 7, the circuit element layer CL may form a switching transistor Tsw and a driving transistor Tdr. The driving transistor Tdr corresponds to the first transistor T1 of FIG. 3, and the switching transistor Tsw corresponds to any one of the second to seventh transistors T2 - T7 of FIG. 3.

The buffer layer BFL is disposed on the base substrate BL and serves to prevent the diffusion of impurities, to prevent the penetration of moisture or external air, and to planarize the surface. For example, the buffer layer BFL may be formed of an inorganic material such as silicon oxide, silicon nitride, aluminum oxide, aluminum nitride, titanium oxide, or titanium nitride, or an organic material such as polyimide, polyester, or acrylic, or a laminate thereof.

The first active pattern ACT1 and the second active pattern ACT2 are disposed on the base substrate BL and the buffer layer BFL. In an example, the first active pattern ACT1 and the second active pattern ACT2 may be formed of an inorganic semiconductor such as amorphous or polycrystalline silicon, or an organic semiconductor. The first active pattern ACT1 provides a signal input/output channel for the switching transistor Tsw, and the second active pattern ACT2 provides a signal input/output channel for the driving transistor Tdr.

The first insulating layer CIL1 is disposed on the active patterns ACT1, ACT2 and covers the active patterns ACT1, ACT2. In an example, the first insulating layer CIL1 may be formed of, but not limited to, a laminate including silicon oxide. The first insulating layer CIL1 may function as a gate insulator for both the switching transistor Tsw and the driving transistor Tdr.

The first gate pattern GE1 and the second gate pattern GE2 are disposed on the first insulating layer CIL1. The first gate pattern GE1 may be disposed to overlap the first active pattern ACT1, and the second gate pattern GE2 may be disposed to overlap the second active pattern ACT2. The first gate pattern GE1 may serve as a gate electrode of the switching transistor Tsw, and the second gate pattern GE2 may serve as a gate electrode of the driving transistor Tdr. In one example, the first gate pattern GE1 may be electrically connected to the gate line GL or the light emission control line EL described above.

The second insulating layer CIL2 is disposed on the first and second gate patterns GE1, GE2 and covers the first and second gate patterns GE1, GE2. In one example, the second insulating layer CIL2 may be formed of, but not limited to, a laminate including silicon oxide or silicon nitride. The second insulating layer CIL2 may function as a dielectric of the capacitor Cst described in FIG. 3.

The third gate pattern GE3 is disposed on the second insulating layer CIL2. The third gate pattern GE3 may be disposed to overlap the first gate pattern GE1. The first gate pattern GE1 and the third gate pattern GE3 may function as the capacitor Cst described in FIG. 3. By forming the capacitor Cst to overlap a region corresponding to the driving transistor Tdr, the pixel PX can be miniaturized and integrated, thereby enhancing the resolution of the display device DD. However, the third gate pattern GE3 is not limited to this arrangement and may not be disposed to overlap a region corresponding to the driving transistor Tdr.

The third insulating layer CIL3 is disposed on the second insulating layer CIL2 and the third gate pattern GE3 and covers the third gate pattern GE3. In one example, the third insulating layer CIL3 may be formed of, but not limited to, a laminate including silicon oxide or silicon nitride. Contact holes may be formed in the third insulating layer CIL3 for forming the input/output patterns CNT1 - CNT4.

The input/output patterns CNT1 - CNT4 are disposed on the third insulating layer CIL3 and may contact the active patterns ACT1, ACT2 through the contact holes. A first input pattern CNT1 and a first output pattern CNT2 pass through the first through third insulating layers CIL1 - CIL3 and contact the first active pattern ACT1. A second input pattern CNT3 and a second output pattern CNT4 pass through the first through third insulating layers CIL1 - CIL3 and contact the second active pattern ACT2. The first input pattern CNT1 and the first output pattern CNT2 may serve as the input electrode and output electrode of the switching transistor Tsw, and the second input pattern CNT3 and the second output pattern CNT4 may serve as the input electrode and output electrode of the driving transistor Tdr. In one example, at least a portion of the input/output patterns CNT1 - CNT4 may be electrically connected to the data line DL or the power line VL described above.

The fourth insulating layer CIL4 may provide an upper surface on which the display element layer ELL may be formed. While the fourth insulating layer CIL4 provides a generally flat upper surface, it may provide a concave upper surface facing the display element layer ELL to accommodate a concave-shaped pixel electrode AE, which will be described below. The fourth insulating layer CIL4 may be formed as a single layer or a multiple layers made of an organic material or an inorganic material. A contact hole may be formed in the fourth insulating layer CIL4 to electrically connect at least a portion of the input/output patterns CNT1 - CNT4. A contact pattern formed in the contact hole may transfer a driving current, provided from the circuit element layer CL, to the display element layer ELL.

The display element layer ELL is disposed on the circuit element layer CL and corresponds to the light-emitting diode ED described in FIG. 3. The display element layer ELL may include a pixel electrode AE, a pixel defining layer PDL, a light-emitting layer EML, and an opposing electrode CE. The configuration of the display element layer ELL is illustrated in a simplified manner for convenience of explanation.

The pixel electrode AE is disposed on the fourth insulating layer CIL4. The pixel electrode AE may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). The pixel electrode AE may serve as an anode electrode of the light-emitting diode ED. The pixel electrode AE may have a concave upper surface facing the light-emitting layer EML. The pixel electrode AE may have a concave shape relative to the direction from which external light is incident. In one example, the pixel electrode AE may include a curved surface having a center of curvature in the upper portion thereof. The concave shape of the pixel electrode AE may improve variations in color and luminance of an image that occur depending on the viewing angle when the display device DD displays an image. Specifically, when the pixel electrode AE is flat, the difference in optical path length of light reflected in the third direction DR3 (i.e., 2 × the thickness of the light-emitting layer EML) is greater than that of light reflected in a direction intersecting the third direction DR3 (i.e., 2 × the thickness of the light-emitting layer EML × cosθ). As a result, the spectral width for resonance is reduced, leading to a bluish tint and decreased luminance in the image as viewed from an oblique angle. The concave pixel electrode AE may reduce changes in optical path length variation depending on the viewing angle, thereby reducing variations in perceived color and luminance.

The concave shape of the pixel electrode AE may cause the reflectance color of the pixel region PXA in a non-display state, with the specular component excluded (SCE), to appear greenish and bluish. The concave shape of the pixel electrode AE may alter the overall surface characteristics. As a result, compared to a case where the pixel electrode AE is flat, the reflectance color of the pixel region PXA measured on a planar surface may shift toward greenish and bluish tones. An optical functional unit 230, which will be described later, may shift the reflectance color of the pixel region PXA toward reddish and yellowish tones.

In a non-driven state in which no driving current flows, the display element layer ELL may reflect light corresponding to blue at a higher reflectance than light corresponding to yellow, based on the concave shape of the pixel electrode AE. This may indicate that the maximum reflectance within the wavelength band corresponding to blue is greater than the maximum reflectance within the wavelength band corresponding to yellow and that the minimum reflectance within the wavelength band corresponding to blue is also greater than the minimum reflectance within the wavelength band corresponding to yellow. Furthermore, based on the concave shape of the pixel electrode AE, the display element layer ELL may reflect light corresponding to green at a higher reflectance than light corresponding to red.

The pixel defining layer PDL is disposed on the pixel electrode AE and the fourth insulating layer CIL4. An opening is formed in the pixel defining layer PDL, through which at least a portion of the pixel electrode AE not overlapped by the pixel defining layer. The pixel defining layer PDL defines, through the opening, an area corresponding to one pixel. Within the display unit 210, the pixel defining layer PDL defines a non-emission region overlapping the pixel defining layer and an emission region exposed through the opening. The pixel defining layer PDL may include a dye or pigment having a black color. The pixel electrode AE includes a first upper surface UP1,and a second upper surface UP2. The first upper surface UP1 may be recessed with respect to the light-emitting layer EML and not overlap the pixel defining layer PDL. T he second upper surface UP2 may extend from the first upper surface and overlap the pixel defining layer.

The light-emitting layer EML is disposed on the pixel electrode AE and the pixel defining layer PDL. The light-emitting layer EML includes a light-emitting material. In one example, the light-emitting layer EML may include an organic material containing a fluorescent or phosphorescent substance that emits red, green, or blue light. The light-emitting layer EML may include a low-molecular-weight organic material or a high-molecular-weight organic material. The light-emitting layer EML may have a concave shape relative to its upper side by conforming to the concave upper surface of the pixel electrode AE. As a result, the viewing angle of light emitted from the light-emitting layer EML may be widened, and image quality with respect to the viewing angle may be improved.

Although not illustrated, the display element layer ELL may further include a hole control layer, such as a hole transport layer (HTL) and a hole injection layer (HIL), between the light-emitting layer EML and the pixel electrode AE. Additionally, although not shown, the display element layer ELL may further include an electron control layer, such as an electron transport layer (ETL) and an electron injection layer (EIL), between the light-emitting layer EML and the opposing electrode CE.

The opposing electrode CE is disposed on the light-emitting layer EML and the pixel defining layer PDL. The opposing electrode CE may be commonly disposed for a plurality of pixels PX_1. The opposing electrode CE may have a concave shape relative to its upper side by conforming to the concave upper surface of the light-emitting layer EML. The opposing electrode CE may be a light-transmitting electrode or a reflective electrode. Alternatively, the opposing electrode CE may be a transparent or semi-transparent electrode. The opposing electrode CE may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). The opposing electrode CE may serve as a cathode electrode of the light-emitting diode ED. The opposing electrode CE may have a concave shape along the light-emitting layer EML. As a result, the viewing angle of light emitted from the display element may be widened, and image quality with respect to the viewing angle may be improved.

The encapsulation layer TFE is disposed on the opposing electrode CE. The encapsulation layer TFE covers the concave shape of the display element layer ELL. The encapsulation layer TFE may include at least one inorganic encapsulation layer and at least one organic encapsulation layer. The encapsulation layer TFE may be configured to protect the display element layer ELL from external moisture or contaminants.

The input sensing unit 220 may be disposed on the encapsulation layer TFE. The input sensing unit 220 may be configured to detect an external input applied from the outside. The input sensing unit 220 corresponds to the input sensing unit 220 described in FIGS. 2 and 6 and thus will not be described redundantly. Contrary to the illustration, the display device DD or the electronic panel 200 may not include the input sensing unit 220, in which case the pixel PX_1 may not include the input sensing unit 220.

The optical functional unit 230 may be disposed on the display unit 210 and the input sensing unit 220. The optical functional unit 230 includes a light-blocking layer BM, a color filter CF, a transparent coating layer OCL, and a color control layer YCL.

The light-blocking layer BM is disposed on the display unit 210 and the input sensing unit 220. The light-blocking layer BM overlaps the pixel defining layer PDL. That is, the light-blocking layer BM may be disposed in a non-emission region of the pixel PX_1. The light-blocking layer BM includes a material configured to prevent reflection of external light and may include a dye or pigment having a black color.

The color filter CF is disposed on the display unit 210 and the input sensing unit 220. The color filter CF overlaps the light-emitting layer EML. That is, the color filter CF may be disposed in an emission region of the pixel PX_1. Additionally, a portion of the color filter CF may overlap a non-emission region. The color filter CF may transmit light within a specific wavelength band corresponding to the color generated by the light-emitting layer EML. The color filter CF may prevent reflection of external light in wavelength bands other than the target wavelength band. For example, in a pixel PX_1 configured to emit light corresponding to red, the color filter CF may transmit light in the red wavelength band.

The color filter CF may be configured to improve a portion of the reflectance color caused by the concave shape of the pixel electrode AE. In one example, the color filter CF may shift a greenish reflectance color, resulting from the concave shape of the pixel electrode AE, to a reddish tone. To this end, the color filter CF corresponding to red may cover a wider area of the pixel region PXA than color filters corresponding to other colors. For example, the color filter CF corresponding to red may overlap the light-emitting layer EML corresponding to red and may further overlap overall non-emission regions of pixels corresponding to red and other colors.

The transparent coating layer OCL is disposed on the display unit 210 and the input sensing unit 220 and covers the light-blocking layer BM and the color filter CF. The transparent coating layer OCL may include a transparent organic material. The transparent coating layer OCL may provide a flat upper surface.

The color control layer YCL may be disposed on the transparent coating layer OCL. The color control layer YCL may be configured to improve a portion of the reflectance color caused by the concave shape of the pixel electrode AE. In one example, the color control layer YCL may shift a bluish reflectance color, resulting from the concave shape of the pixel electrode AE, to a yellowish tone. To this end, the color control layer YCL is disposed to overlap at least a non-emission region of the pixel PX_1. The color control layer YCL may overlap at least a portion of the pixel defining layer PDL surrounding the pixel electrode AE. Specifically, the color control layer YCL may overlap at least an upper surface of the pixel electrode AE corresponding to the non-emission region. According to embodiments to be described later, the color control layer YCL may be disposed to overlap at least a portion of the emission region of the pixel PX_1.

The color control layer YCL includes amorphous silicon. In one example, the color control layer YCL may be formed by depositing amorphous silicon on the transparent coating layer OCL. Depending on its thickness, amorphous silicon transmits visible light but may transmit light of specific wavelength bands more than others. With the application of amorphous silicon, the transmittance of light in the wavelength band corresponding to yellow in the visible light range may be higher than the transmittance of light in the wavelength band corresponding to other colors (e.g., blue). This may indicate that the maximum transmittance in the wavelength band corresponding to yellow is greater than the maximum transmittance in the blue band, and the minimum transmittance in the wavelength band corresponding to yellow is greater than the minimum transmittance in the blue band.

The color control layer YCL may have a higher transmittance for light in the wavelength band corresponding to yellow than for other wavelength bands. As the thickness of the color control layer YCL, which includes amorphous silicon, increases in the third direction DR3, the wavelength at which the highest transmittance occurs and the wavelength at which the lowest reflectance occurs may both increase. The color control layer YCL may have a thickness configured to achieve maximum transmittance and minimum reflectance within a wavelength band of approximately 570 nm to 590 nm. Additionally, the color control layer YCL may have a thickness such that the reflectance color does not become excessively yellowish. In one example, the thickness of the color control layer YCL may be in the range of 40 Å to 60 Å.

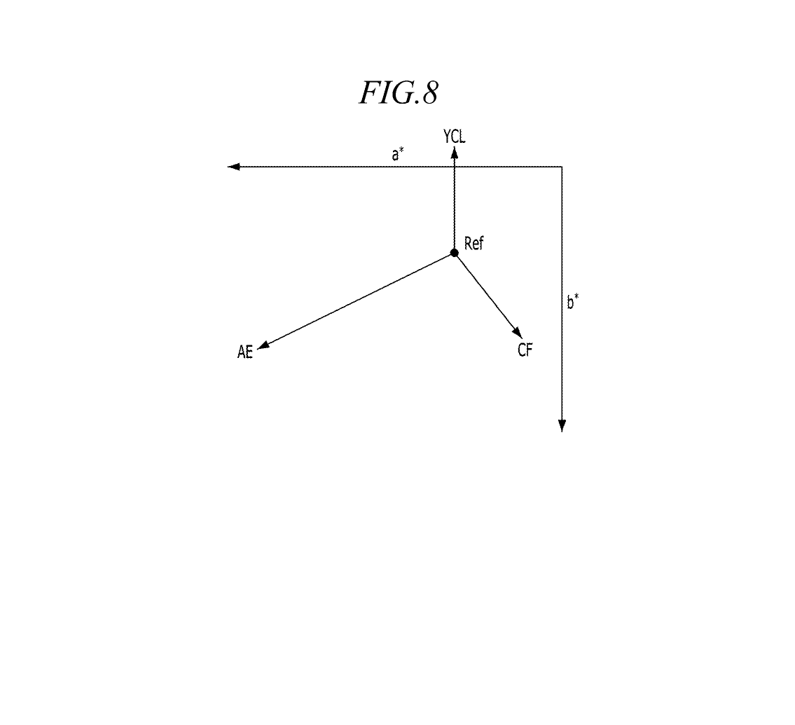

FIG. 8 is a graph illustrating improvement in reflectance color of the display device according to an embodiment of the present disclosure. Referring to FIG. 8, the reflectance color (SCE) of a pixel region in a non-driven state of the display device (i.e., when the voltage between the pixel electrode and the opposing electrode is lower than the driving voltage of the light-emitting layer) is illustrated. The graph in FIG. 8 represents color coordinates (a*, b*) of the reflectance color. When a* is positive, the pixel region exhibits a reddish color; when a* is negative, the pixel region exhibits a greenish color. When b* is positive, the pixel region exhibits a yellowish color; when b* is negative, the pixel region exhibits a bluish color.

A display device that does not include a concave pixel electrode AE, a color filter CF, or a color control layer YCL as described in FIG. 7 is defined as a reference display device (Ref). When the display device includes a concave pixel electrode AE, the reflectance color may shift to greenish and bluish, as described above.

When the display device includes a color filter CF, the reflectance color may shift to reddish, as described above. If a color filter CF corresponding to red is disposed to overlap the entire non-emission region, the reflectance color may shift to a reddish tone. Similarly, if a color filter CF corresponding to blue is disposed to overlap the entire non-emission region, the reflectance color may shift to a bluish tone. Through the use of color filters CF overlapping the non-emission regions, a color enhancement where a* becomes positive, i.e., a shift to a reddish tone, can be achieved. However, when the color filter CF includes red, green, and blue color filters, it may be difficult to achieve a color enhancement in which b* becomes positive, i.e., a shift to a yellowish tone, using only the color filter CF.

When the display device includes the color control layer YCL, the reflectance color may shift to yellowish, as described above. If the color control layer YCL corresponding to yellow is disposed to overlap the pixel region, the reflectance color may shift to yellowish. By using the color control layer YCL, a color enhancement in which b* becomes positive , i.e., a shift to yellowish, can be achieved, and the reflectance color caused by the concave pixel electrode AE can be shifted accordingly.

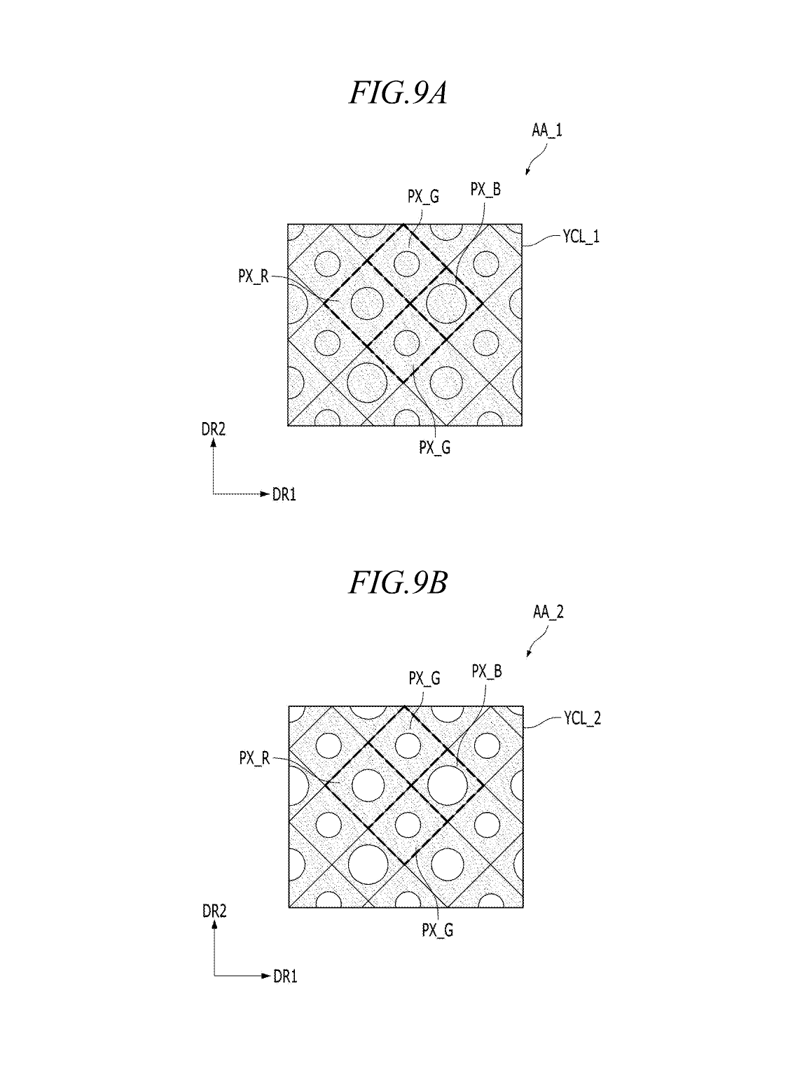

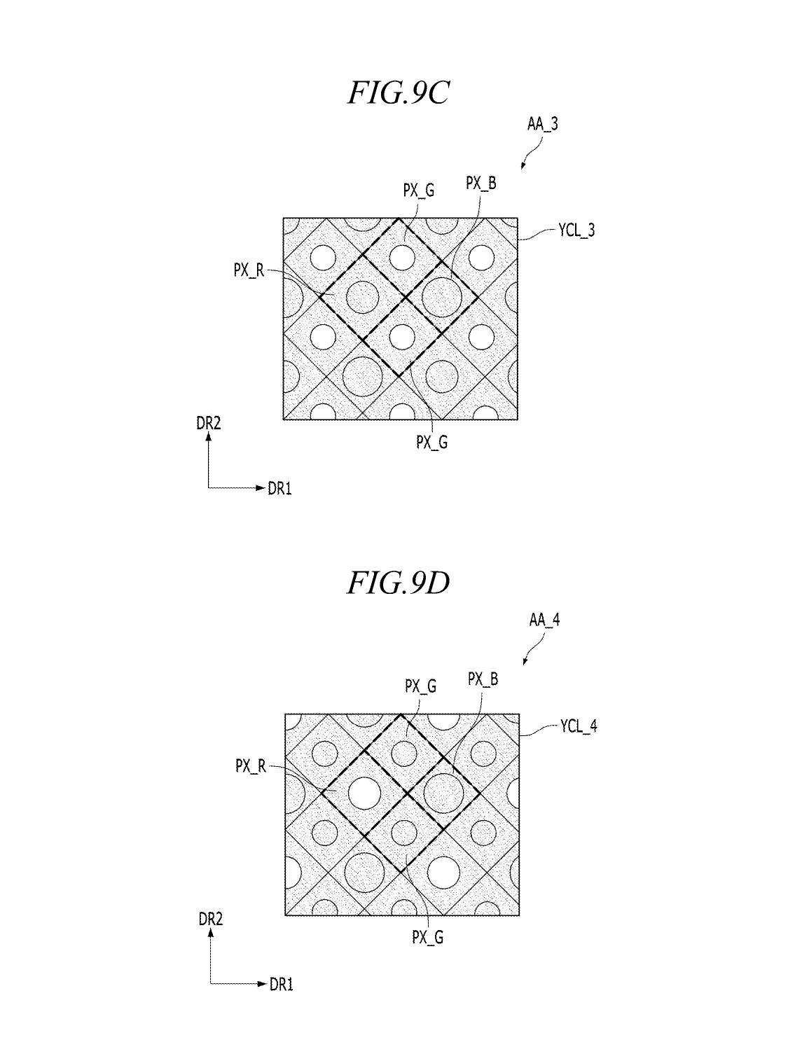

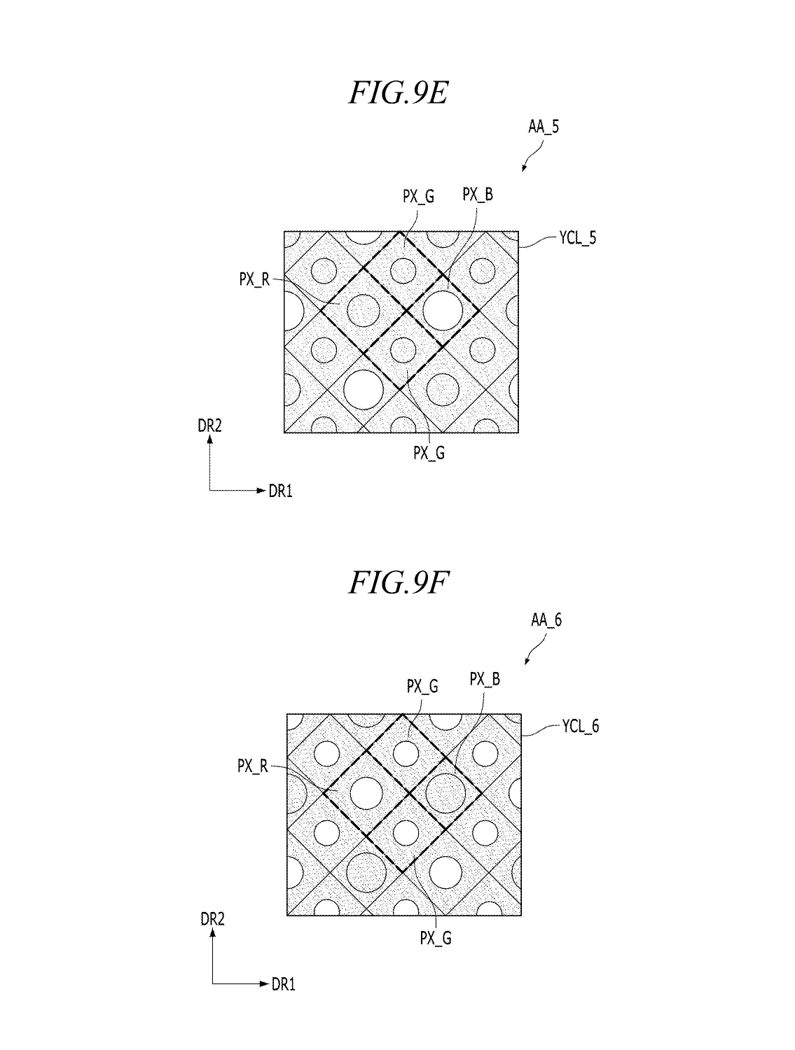

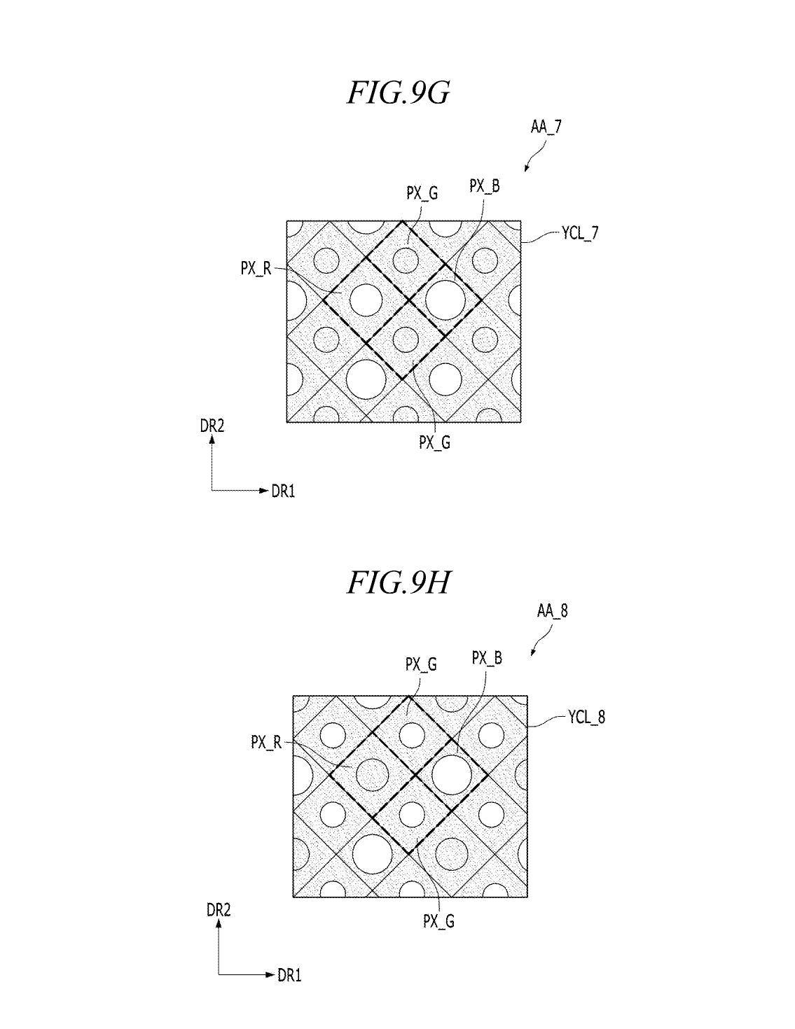

FIGS. 9A to 9H are plan views illustrating examples of the color control layer shown in FIG. 7. Referring to FIGS. 9A to 9H, color control layers YCL_1 – YCL_8 are provided in pixel regions AA_1 – AA_8. A plurality of pixels PX_G, PX_B, PX_R are provided in the pixel regions AA_1 – AA_8. Emission regions for outputting light from the plurality of pixels PX_G, PX_B, PX_R are defined by the pixel defining layer PDL described above. Although the emission regions are illustrated as circular, the shape is not limited thereto, and the emission regions may alternatively be formed in various shapes, such as diamond or rectangular. The non-emission region may be understood as a region overlapping the pixel defining layer PDL.

Red pixels PX_R configured to emit light corresponding to red, green pixels PX_G configured to emit light corresponding to green, and blue pixels PX_B configured to emit light corresponding to blue may be arranged two-dimensionally on a plane parallel to the first direction DR1 and the second direction DR2. In one example, one red pixel PX_R, one blue pixel PX_B, and two green pixels PX_G may constitute a pixel unit for outputting a desired color; however, the configuration is not limited thereto.

Referring to FIG. 9A, the color control layer YCL_1 overlaps the pixel region AA_1. The color control layer YCL_1 may be disposed to overlap both the emission region and the non-emission region. In this case, the color control layer YCL_1 may most effectively improve the bluish reflectance color in a non-driven state caused by the concave pixel electrode AE. For example, the color control layer YCL_1 may have a thickness that results in a higher transmittance for light corresponding to yellow than for light corresponding to blue. The color control layer YCL_1 may be configured to have a visible light transmittance that does not alter the output image of the emission region. For instance, the color control layer YCL_1 may have a thickness that ensures its visible light transmittance exceeds a reference threshold.

Referring to FIG. 9B, the color control layer YCL_2 may be disposed to not overlap the emission region and to overlap the non-emission region. In other words, the color control layer YCL_2 may be disposed to not overlap at least a portion of the light-emitting layer EML and to overlap the pixel defining layer PDL. The color control layer YCL_2 may be patterned to expose the emission region. In the third direction DR3, the color control layer YCL_2 and the pixel electrode AE may not overlap. Compared to the color control layer YCL_1 of FIG. 9A, the color control layer YCL_2 may result in a less pronounced shift in reflectance color toward yellow, but may allow light to pass through without affecting the image displayed by the emission region.

The color control layer YCL_2 may cover at least the non-emission region. Specifically, the pixel electrode AE as shown in FIG. 7 may have a concave shape and may include an exposed surface (first upper surface) corresponding to the emission region and a non-exposed surface (second upper surface) extending from the exposed surface and overlapping the pixel defining layer PDL. Even if the color control layer YCL_2 is patterned as shown in FIG. 9B and subsequent figures, it may still overlap at least the non-exposed surface (second upper surface) of the pixel electrode AE. Furthermore, due to the concave shape of the pixel electrode AE, the color control layer YCL _2 may overlap at least a portion of the pixel electrode AE in the normal direction of the pixel electrode AE.

Referring to FIG. 9C, the color control layer YCL_3 may be disposed to not overlap the emission region corresponding to the green pixel PX_G and to overlap the emission regions corresponding to the red pixel PX_R and the blue pixel PX_B. Referring to FIG. 9D, the color control layer YCL_4 may be disposed to not overlap the emission region corresponding to the red pixel PX_R and to overlap the emission regions corresponding to the green pixel PX_G and the blue pixel PX_B. Referring to FIG. 9E, the color control layer YCL_5 may be disposed to not overlap the emission region corresponding to the blue pixel PX_B and to overlap the emission regions corresponding to the green pixel PX_G and the red pixel PX_R.

The color control layers YCL_3 - YCL_5 shown in FIGS. 9C to 9E may overlap the non-emission regions and may be selectively patterned to expose the emission regions of specific color pixels. Accordingly, the color control layers YCL_3 - YCL_5 may achieve a greater change in reflectance color than the color control layer YCL_2 of FIG. 9B, while reducing the impact on the output image compared to the color control layer YCL_1 of FIG. 9A. The color control layers YCL_3 - YCL_5 may be selected in consideration of both the reflectance color in a non-emission state altered by the concave pixel electrode AE and the color tone of the output image in an emission state.

Referring to FIG. 9F, the color control layer YCL_6 may be disposed to not overlap the emission regions corresponding to the red pixel PX_R and the green pixel PX_G and to overlap the emission region corresponding to the blue pixel PX_B. Referring to FIG. 9G, the color control layer YCL_7 may be disposed to not overlap the emission regions corresponding to the red pixel PX_R and the blue pixel PX_B and to overlap the emission region corresponding to the green pixel PX_G. Referring to FIG. 9H, the color control layer YCL_8 may be disposed to not overlap the emission regions corresponding to the green pixel PX_G and the blue pixel PX_B and to overlap the emission region corresponding to the red pixel PX_R.

The color control layers YCL_6 - YCL_8 shown in FIGS. 9F to 9H may overlap the non-emission regions and may be selectively patterned to expose the emission regions of two specific color pixels. Accordingly, the color control layers YCL_6 - YCL_8 may achieve a greater change in reflectance color than the color control layer YCL_2 of FIG. 9B, while exerting less influence on the output image compared to the color control layer YCL_1 of FIG. 9A and the color control layers YCL_3 - YCL_5 of FIGS. 9C to 9E. The color control layers YCL_6 - YCL_8 may be selected in consideration of both the reflectance color in a non-emission state, which is altered by the concave pixel electrode AE and the color tone of the output image during emission.

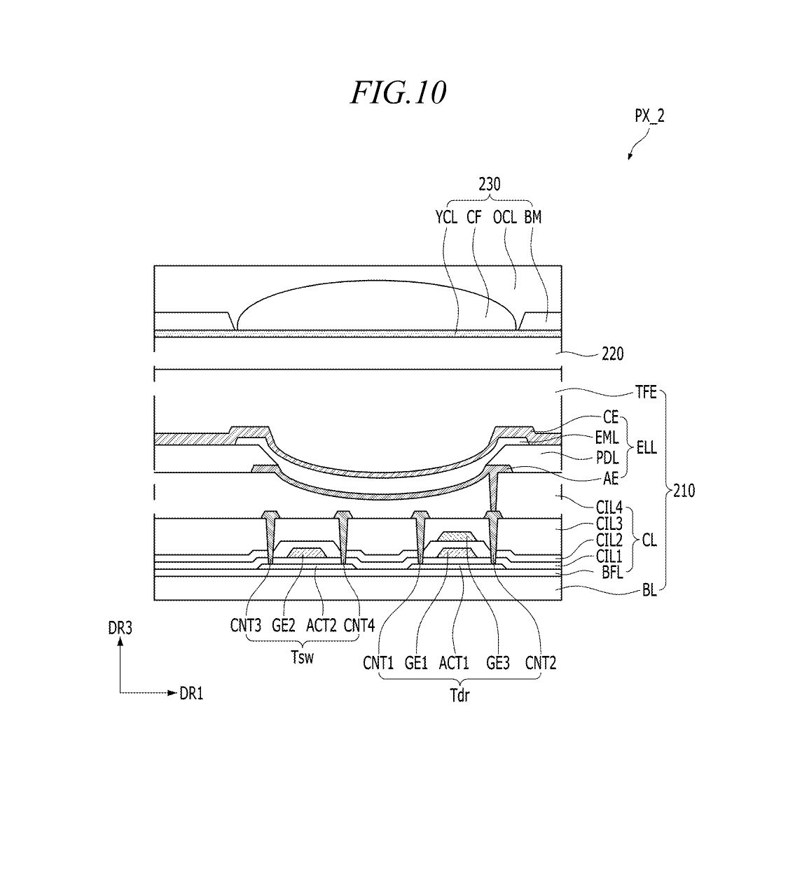

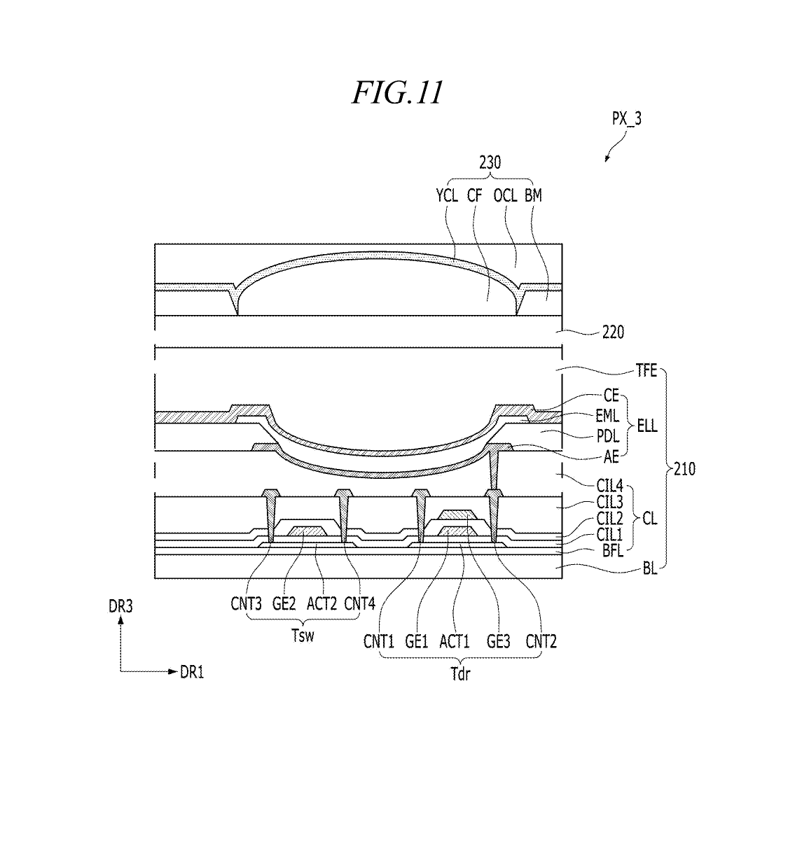

FIG. 10 is a cross-sectional view of a pixel according to an embodiment of the present disclosure. Referring to FIG. 10, the pixel PX_2 includes a display unit 210, an input sensing unit 220, and an optical function unit 230. The display unit 210 and the input sensing unit 220 are substantially the same as the display unit 210 and the input sensing unit 220 of FIG. 7 and thus will not be described redundantly. The optical function unit 230 includes a light-blocking layer BM, a color filter CF, a transparent coating layer OCL, and a color control layer YCL.

Compared to FIG. 7, the color control layer YCL may be disposed below the light-blocking layer BM, the color filter CF, and the transparent coating layer OCL. In one example, the color control layer YCL may be formed by depositing it on an upper surface of the input sensing unit 220 before forming the light-blocking layer BM, the color filter CF, and the transparent coating layer OCL on the input sensing unit 220. The color control layer YCL may be disposed between the input sensing unit 220 (or the display unit 210 such as the encapsulation layer TFE) and the transparent coating layer OCL (or the color filter CF or the light-blocking layer BM). Other characteristics of the color control layer YCL are substantially the same as those of the color control layer YCL shown in FIG. 7. The planar shape of the color control layer YCL may correspond to the shapes described in FIGS. 9A to 9H.

FIG. 11 is another cross-sectional view illustrating a pixel according to an embodiment of the present disclosure. Referring to FIG. 11, the pixel PX_3 includes a display unit 210, an input sensing unit 220, and an optical function unit 230. The display unit 210 and the input sensing unit 220 are substantially the same as the display unit 210 and the input sensing unit 220 of FIG. 7 and thus will not be described redundantly. The optical function unit 230 includes a light-blocking layer BM, a color filter CF, a transparent coating layer OCL, and a color control layer YCL.

Compared to FIG. 7, the color control layer YCL may be disposed between the color filter CF and the transparent coating layer OCL. The color control layer YCL may be disposed between the light-blocking layer BM and the transparent coating layer OCL but is not limited thereto and may also be disposed below the light-blocking layer BM. In one example, the color control layer YCL may be formed by deposition after forming the color filter CF on the input sensing unit 220. Other characteristics of the color control layer YCL are substantially the same as those of the color control layer YCL shown in FIG. 7. The planar shape of the color control layer YCL may correspond to the shapes described in FIGS. 9A to 9H.

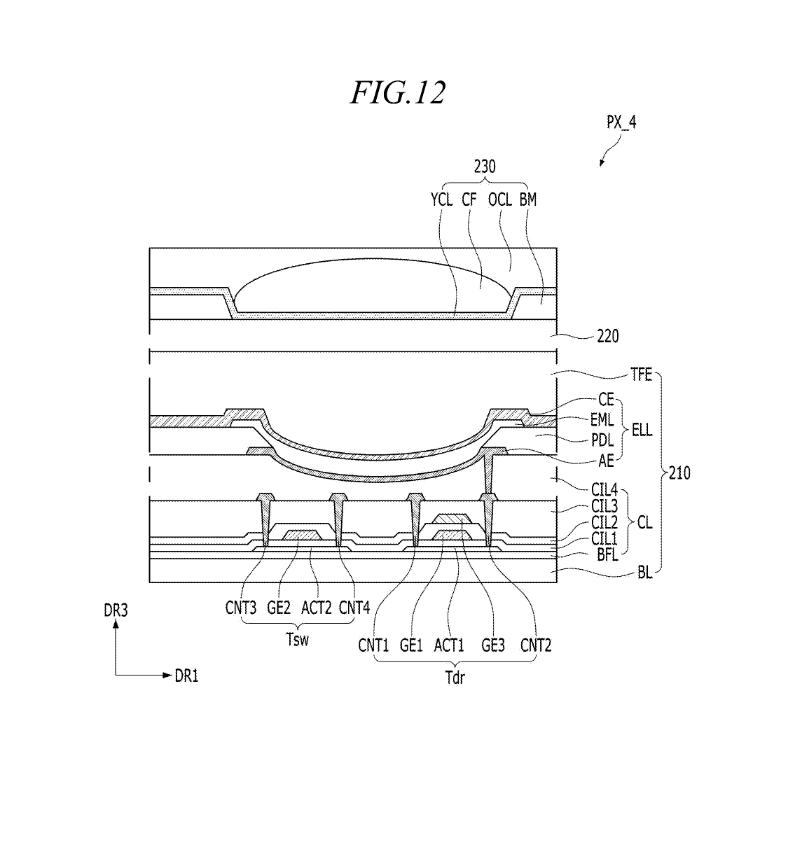

FIG. 12 is another cross-sectional view illustrating a pixel according to an embodiment of the present disclosure. Referring to FIG. 12, the pixel PX_4 includes a display unit 210, an input sensing unit 220, and an optical function unit 230. The display unit 210 and the input sensing unit 220 are substantially the same as those of FIG. 7 and thus will not be described redundantly. The optical function unit 230 includes a light-blocking layer BM, a color filter CF, a transparent coating layer OCL, and a color control layer YCL.

Compared to FIG. 7, the color control layer YCL may be disposed between the light-blocking layer BM and the transparent coating layer OCL. The color control layer YCL may be disposed below the color filter CF but is not limited thereto and may be disposed between the color filter CF and the transparent coating layer OCL. In one example, the color control layer YCL may be formed by deposition after the light-blocking layer BM is formed on the input sensing unit 220. Other characteristics of the color control layer YCL are substantially the same as those of the color control layer YCL shown in FIG. 7. The planar shape of the color control layer YCL may correspond to the shapes described in FIGS. 9A to 9H.

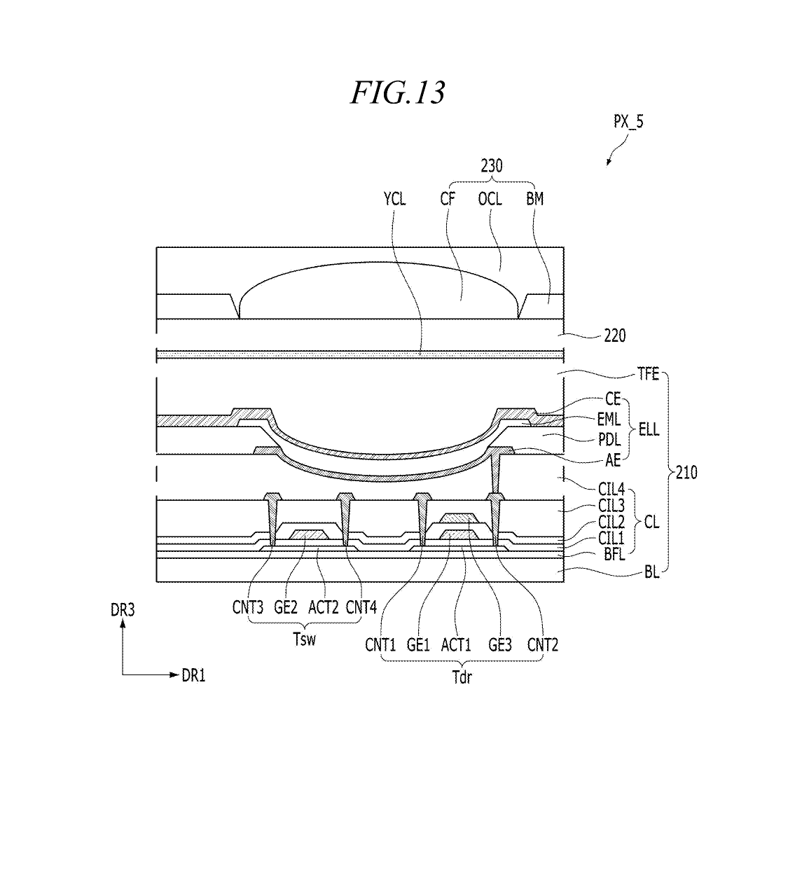

FIG. 13 is another cross-sectional view illustrating a pixel according to an embodiment of the present disclosure. Referring to FIG. 13, the pixel PX_5 includes a display unit 210, an input sensing unit 220, and an optical function unit 230. The display unit 210 and the input sensing unit 220 are substantially the same as those illustrated in FIG. 7 and thus will not be described redundantly. The optical function unit 230 includes a light-blocking layer BM, a color filter CF, and a transparent coating layer OCL.

Compared to FIG. 7, a color control layer YCL may be disposed between the display unit 210 and the input sensing unit 220. In one example, the color control layer YCL may be formed by deposition on an encapsulation layer TFE of the display unit 210 prior to forming the input sensing unit 220. Other characteristics of the color control layer YCL are substantially the same as those described in FIG. 7. The planar shape of the color control layer YCL may correspond to the shapes described in FIGS. 9A to 9H.

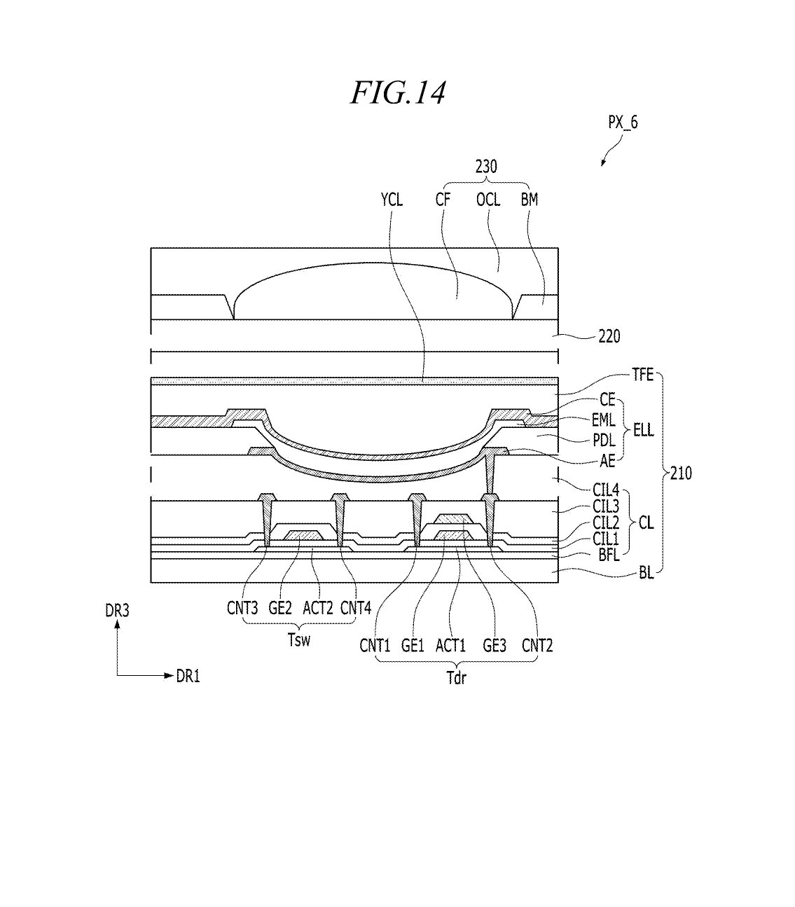

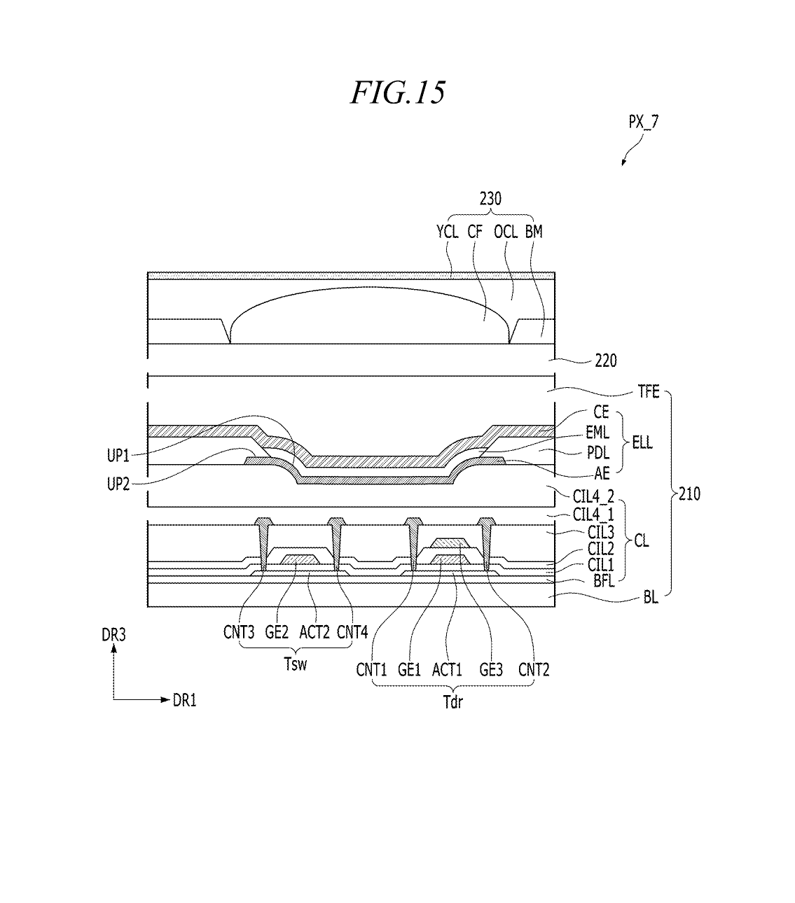

FIG. 14 is another cross-sectional view illustrating a pixel according to an embodiment of the present disclosure. Referring to FIG. 14, the pixel PX_6 includes a display unit 210, an input sensing unit 220, and an optical function unit 230, which correspond, respectively, to the display unit 210, the input sensing unit 220, and the optical function unit 230 of FIG. 7. The optical function unit 230 includes a light-blocking layer BM, a color filter CF, and a transparent coating layer OCL.

Compared to FIG. 7, a color control layer YCL may be disposed inside an encapsulation layer TFE of the display unit 210. The encapsulation layer TFE may include at least one inorganic layer and at least one organic layer. The at least one inorganic layer and the at least one organic layer may be stacked. The color control layer YCL may be disposed between the at least one inorganic layer and the at least one organic layer. In one example, the color control layer YCL may be formed by deposition on either the organic or inorganic layer during the process of forming the encapsulation layer TFE. Other characteristics of the color control layer YCL are substantially the same as those described in FIG. 7. The planar shape of the color control layer YCL may correspond to the shapes described in FIGS. 9A to 9H.

FIG. 15 is another cross-sectional view illustrating a pixel according to an embodiment of the present disclosure. Referring to FIG. 15, the pixel PX_7 includes a display unit 210, an input sensing unit 220, and an optical function unit 230, which correspond, respectively, to the display unit 210, the input sensing unit 220, and the optical function unit 230 of FIG. 7. While the color control layer YCL is shown as being disposed on the transparent coating layer OCL of the optical function unit 230, as in FIG. 7, it is not limited thereto and may be disposed in any of the locations illustrated in FIGS. 10 through 14. The planar shape of the color control layer YCL may also correspond to the shapes described in FIGS. 9A through 9H.

Compared to FIG. 7, at least a portion of the display element layer ELL of the display unit 210 may be flat. The pixel electrode AE may have a flat upper surface facing the light-emitting layer EML. The pixel electrode AE may also include a convex upper surface extending toward the pixel defining layer PDL from the flat upper surface, based on the direction in which external light is incident. Accordingly, the light-emitting layer EML and the opposing electrode CE may have a flat shape and a convex shape extending from the flat portion. The flat upper surface and convex upper surface of the pixel electrode AE may constitute the exposed surface (first upper surface) corresponding to the light-emitting region. This exposed surface (first upper surface) may be defined as concave relative to the direction in which external light is incident. That is, the term “concave,” as previously mentioned, may be understood not merely as a shape having a center of curvature at the top but as a broader concept that includes shapes where the central portion is farther from the viewer than the peripheral portions (i.e., a recess). A change in the reflectance color caused by the shape of the pixel electrode AE may be shifted by the color control layer YCL.

The circuit element layer CL of the display unit 210 may include a fourth insulation layer including lower and upper insulation layers CIL4_1, CIL4_2. The lower fourth insulation layer CIL4_1 may be disposed on the third insulation layer CIL3 and may provide a flat upper surface. The upper fourth insulation layer CIL4_2 may be disposed on the lower insulation layer CIL4_1 and may provide a flat and convex upper surface corresponding to the shape of the pixel electrode AE. Although not shown, contact holes may be formed in the insulation layers CIL4_1, CIL4_2 to electrically connect the circuit element layer CL and the pixel electrode AE. It shall be understood that the number and shape of the fourth insulation layers CIL4_1, CIL4_2 are illustrative and not limiting. As in the above embodiments, the fourth insulation layer may be implemented as a single layer or more than two layers. Furthermore, the upper insulation layer CIL4_2 may be configured to expose the lower insulation layer CIL4_1 such that the pixel electrode AE contacts the lower insulation layer CIL4_1.

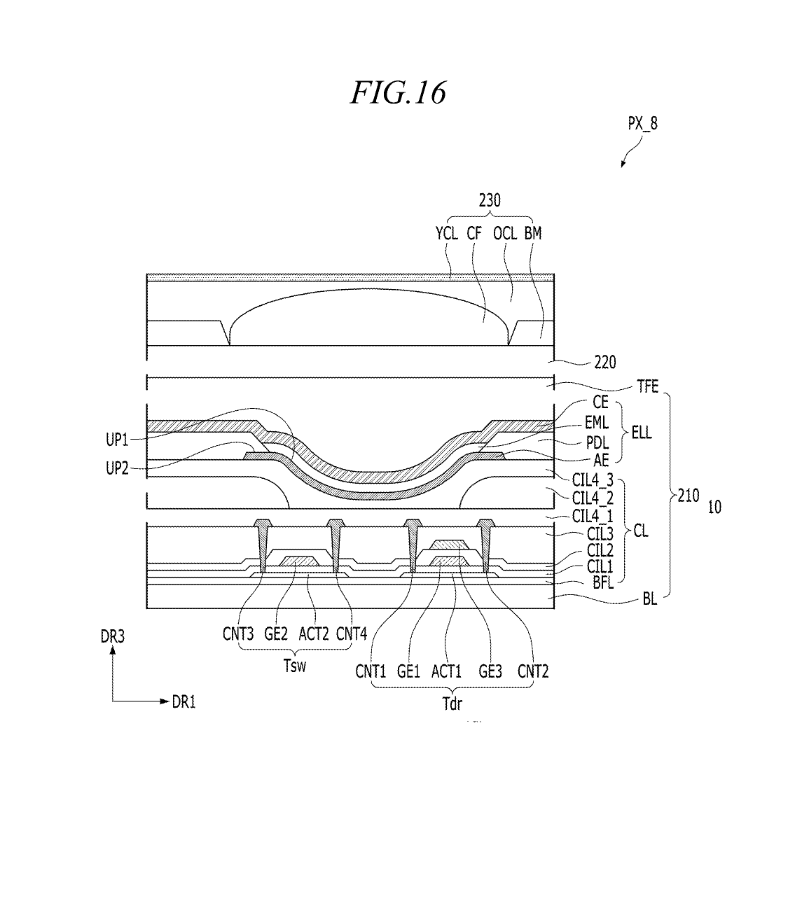

FIG. 16 is another cross-sectional view illustrating a pixel according to an embodiment of the present disclosure. Referring to FIG. 16, a pixel PX_8 includes a display unit 210, an input sensing unit 220, and an optical functional unit 230, which correspond, respectively, to the display unit 210, the input sensing unit 220, and the optical functional unit 230 shown in FIG. 7. A color control layer YCL is illustrated as being disposed on a transparent coating layer OCL of the optical functional unit 230, similar to FIG. 7. However, it is not limited thereto and may be disposed at a position illustrated in FIGS. 10 to 14. Additionally, the planar shape of the color control layer YCL may correspond to the shapes described in FIGS. 9A to 9H.

Compared to FIG. 7, a pixel electrode AE may include a concave upper surface that faces the light-emitting layer EML and a convex upper surface that extends from the concave upper surface toward a pixel defining layer PDL. Accordingly, the light-emitting layer EML and an opposing electrode CE may also have a concave shape and a convex shape extending from the concave shape. The concave and convex upper surfaces of the pixel electrode AE may constitute an exposed surface (first upper surface) corresponding to the emission region. The exposed surface (first upper surface) may be defined as concave based on the fact that its central portion is farther recessed than its peripheral portions with respect to the upper side. The reflectance color altered by the shape of the pixel electrode AE may be shifted by the color control layer YCL.

A circuit element layer CL of the display unit 210 may include fourth insulating layers CIL4_1, CIL4_2, CIL4_3. A lower fourth insulating layer CIL4_1 may be disposed on a third insulating layer CIL3 and provide a flat upper surface. An intermediate fourth insulating layer CIL4_2 may be disposed on the lower fourth insulating layer CIL4_1 and expose a portion of the lower fourth insulating layer CIL4_1. The intermediate fourth insulating layer CIL4_2 may provide a convex upper surface corresponding to the convex shape of the pixel electrode AE. An upper fourth insulating layer CIL4_3 may be disposed on both the lower fourth insulating layer CIL4_1 and the intermediate fourth insulating layer CIL4_2 and may provide a concave upper surface and a convex upper surface corresponding to the shape of the pixel electrode AE. Although not shown, contact holes may be formed in the fourth insulating layers CIL4_1, CIL4_2, CIL4_3, thereby electrically connecting the circuit element layer CL and the pixel electrode AE. It shall be appreciated that the number and shapes of the fourth insulating layers CIL4_1, CIL4_2, CIL4_3 are illustrative and may be implemented in other configurations as illustrated in the foregoing embodiments.

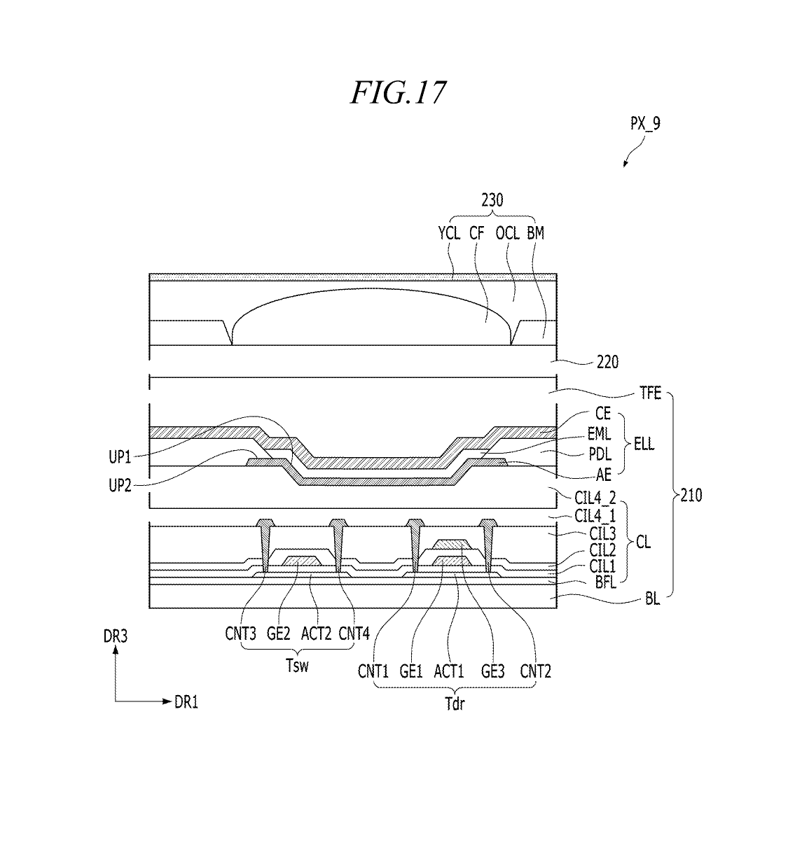

FIG. 17 is another cross-sectional view illustrating a pixel according to an embodiment of the present disclosure. Referring to FIG. 17, a pixel PX_9 includes a display unit 210, an input sensing unit 220, and an optical functional unit 230, which correspond, respectively, to the display unit 210, the input sensing unit 220, and the optical functional unit 230 shown in FIG. 7. A color control layer YCL is illustrated as being disposed on a transparent coating layer OCL of the optical functional unit 230, as in FIG. 7. However, the color control layer YCL is not limited to such a location and may alternatively be disposed at any of the positions illustrated in FIGS. 10 through 14. Additionally, the planar shape of the color control layer YCL may correspond to the shapes described in FIGS. 9A through 9H.

Compared to FIG. 7, at least a portion of a display element layer ELL of the display unit 210 may be flat. A pixel electrode AE may have a flat upper surface that faces the light-emitting layer EML. The pixel electrode AE may further include another flat upper surface that extends at a fixed inclination from the flat upper surface toward a pixel defining layer PDL. Accordingly, the light-emitting layer EML and an opposing electrode CE may also include a flat shape and an inclined shape extending therefrom. The flat upper surface and the inclined upper surface of the pixel electrode AE may define an exposed surface (first upper surface) corresponding to the emission region. This exposed surface (first upper surface) may be defined as concave in that its central portion is recessed farther than its peripheral portion with respect to the upper side. The reflectance color altered by the shape of the pixel electrode AE may be shifted by the color control layer YCL.

A circuit element layer CL of the display unit 210 may include fourth insulating layers CIL4_1, CIL4_2. A lower fourth insulating layer CIL4_1 may be disposed on a third insulating layer CIL3 and may provide a flat upper surface. An upper fourth insulating layer CIL4_2 may be disposed on the lower fourth insulating layer CIL4_1 and may provide a flat upper surface and an inclined upper surface at a fixed inclination corresponding to the shape of the pixel electrode AE. The number and shape of the fourth insulating layers CIL4_1, CIL4_2 are not limited thereto.

The display device DD according to the above-described embodiments may be applied to various electronic devices. An electronic device according to

an embodiment includes the aforementioned display device and may further include modules or devices with additional functions other than the display device.

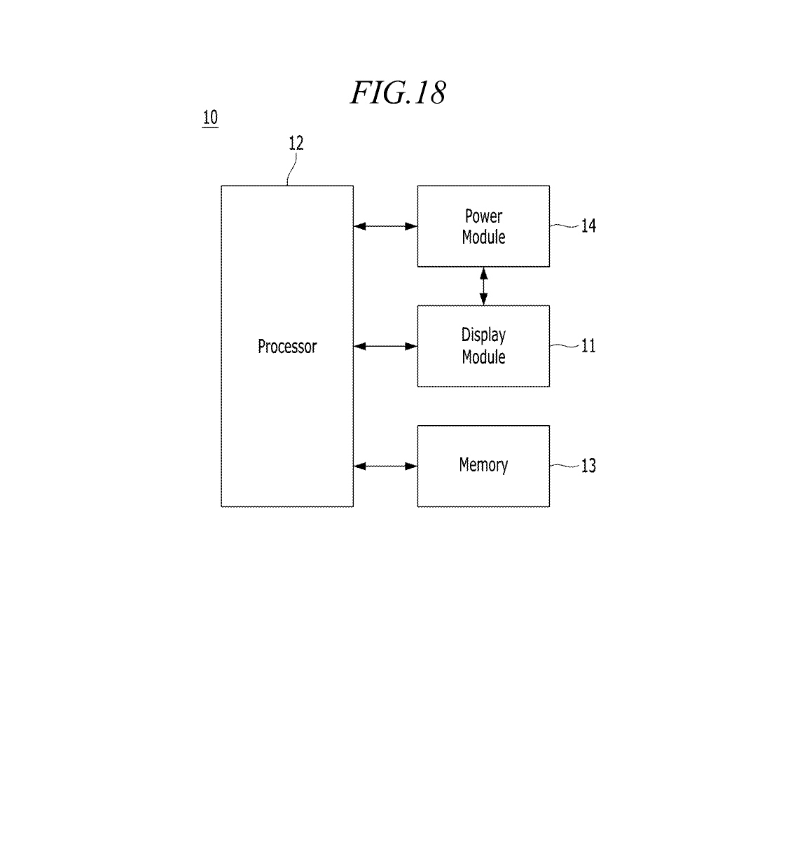

FIG. 18 is a block diagram illustrating an electronic device according to an embodiment. Referring to FIG. 18, the electronic device 10 may include a display module 11, a processor 12, a memory 13, and a power module 14.

The processor 12 may include at least one of a central processing unit (CPU), an application processor (AP), a graphics processing unit (GPU), a communication processor (CP), an image signal processor (ISP), or a controller. The processor 12 may be implemented by more than one processor and the processor 12 may refer to one or more processors.

The memory 13 may have stored therein data and information required for the operation of the processor 12 or the display module 11. When the processor 12 executes an application stored in the memory 13, video data signals or input control signals are transmitted to the display module 11, which may then process the received signals to output video information via a display screen.

The power module 14 may include a power supply module, such as a power adapter or battery device, and a power conversion module configured to convert the power supplied by the power supply module into a form suitable for operating the electronic device 10.

At least one of the components of the electronic device 10 described above may be included in the display device DD according to the embodiments. Additionally, among the individual modules functionally included within one module, some may be incorporated within the display device, while others may be provided separately from the display device. For example, the display device may include the display module 11, while the processor 12, memory 13, and power module 14 may be provided as separate components within the electronic device 10, not as part of the display device.

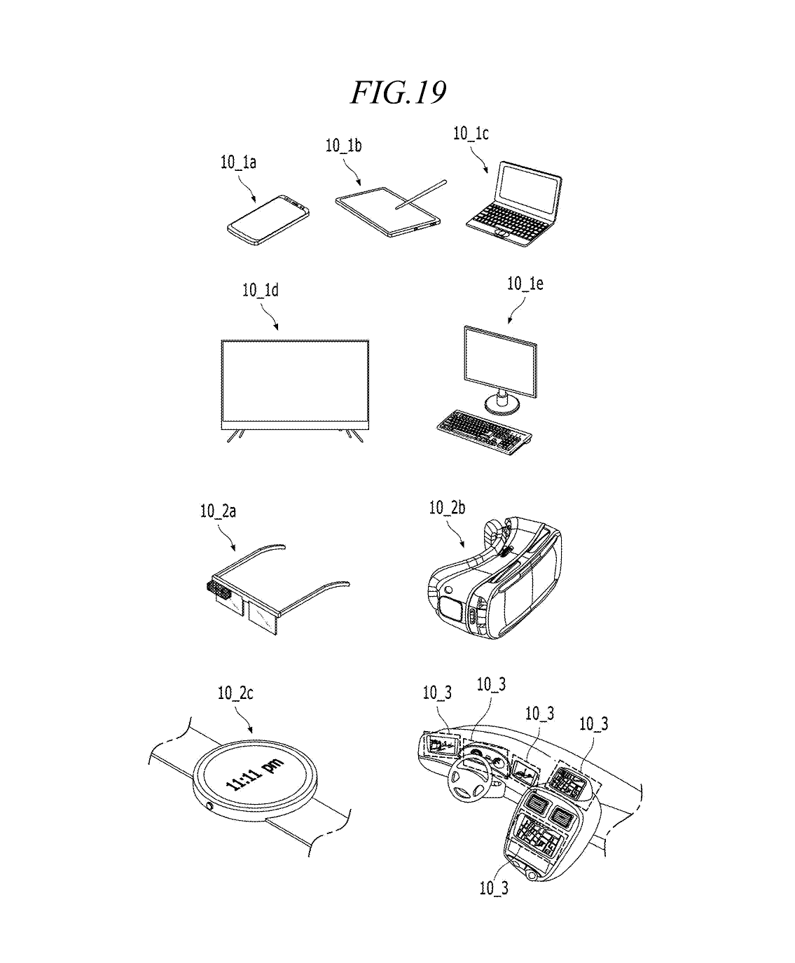

FIG. 19 illustrates schematic views of electronic devices according to various embodiments. Referring to FIG. 19, various electronic devices to which the display device according to embodiments is applied may include not only image displaying electronic devices, such as a smartphone 10_1a, a tablet PC 10_1b, a laptop computer 10_1c, a TV 10_1d, or a desktop monitor 10_1e, but also wearable electronic devices including display modules, such as smart glasses 10_2a, head-mounted displays 10_2b, and smartwatches 10_2c, and automotive electronic devices 10_3 including display modules, such as a center information display (CID) disposed on an instrument panel, center fascia, or dashboard of a vehicle, or a room mirror display.

Embodiments of the present disclosure have been described above, but these are exemples and are not intended to limit the present disclosure. Those skilled in the art to which the present disclosure pertains may make various modifications and changes to the embodiments by adding, changing, deleting, or adding certain elements, without departing from the scope of the technical ideas of the present disclosure as set forth in the claims, and such modifications and changes should also be regarded as being within the scope of the present disclosure.

What is claimed is:

1. A display device comprising:
a base substrate;
a display element layer disposed on the base substrate and comprising a light-emitting layer, a pixel electrode disposed between the light-emitting layer and the base substrate, an opposing electrode facing the pixel electrode with the light-emitting layer interposed therebetween, and a pixel defining layer surrounding the pixel electrode and not overlapping a portion of the pixel electrode;
a circuit element layer disposed between the display element layer and the base substrate and comprising a pixel circuit electrically connected to the pixel electrode; and
a color control layer disposed on the display element layer and comprising amorphous silicon,
wherein the pixel electrode comprises a first upper surface and a second upper surface, the first upper surface being recessed with respect to the light-emitting layer and not overlapping the pixel defining layer, the second upper surface extending from the first upper surface and overlapping the pixel defining layer, and
wherein the color control layer overlaps the second upper surface.

2. The display device of claim 1, further comprising:
an encapsulation layer disposed on the circuit element layer and the display element layer and covering the display element layer; and
a color filter disposed on the encapsulation layer and overlapping the light-emitting layer,
wherein the color filter comprises a red color filter configured to transmit light corresponding to red, and the red color filter overlaps the pixel defining layer.

3. The display device of claim 2, further comprising a transparent coating layer disposed on the encapsulation layer and the color filter and covering the color filter,
wherein the color control layer is disposed on the transparent coating layer.

4. The display device of claim 2, further comprising a transparent coating layer disposed on the encapsulation layer and the color filter and covering the color filter,
wherein the color control layer is disposed between the encapsulation layer and the transparent coating layer.

5. The display device of claim 4, wherein the color control layer is disposed on the color filter.

6. The display device of claim 1, further comprising:
an encapsulation layer disposed on the circuit element layer and the display element layer and covering the display element layer; and
a light-blocking layer disposed on the encapsulation layer and overlapping the pixel defining layer,
wherein the color control layer is disposed on the light-blocking layer.

7. The display device of claim 1, further comprising:
an encapsulation layer disposed on the circuit element layer and the display element layer and covering the display element layer; and
an input sensing unit disposed on the encapsulation layer,
wherein the color control layer is disposed between the encapsulation layer and the input sensing unit.

8. The display device of claim 1, further comprising:
an encapsulation layer disposed on the circuit element layer and the display element layer, covering the display element layer, and comprising an organic film and an inorganic film stacked together,
wherein the color control layer is disposed between the organic film and the inorganic film.

9. The display device of claim 1, wherein the color control layer further overlaps the first upper surface.

10. The display device of claim 1, wherein the color control layer does not overlap the first upper surface.

11. The display device of claim 1, wherein the color control layer, in light-emitting regions defined by the pixel defining layer, does not overlap a light-emitting region that outputs light of a target color and overlaps a light-emitting region that outputs light of a color different from the target color.

12. The display device of claim 1, wherein the color control layer, in light-emitting regions defined by the pixel defining layer, overlaps a light-emitting region that outputs light of a target color and does not overlap a light-emitting region that outputs light of a color different from the target color.

13. A display device comprising:
a base substrate;
a display element layer disposed on the base substrate and comprising a light-emitting layer, a pixel electrode disposed between the light-emitting layer and the base substrate and having a recessed upper surface relative to the light-emitting layer, and an opposing electrode facing the pixel electrode with the light-emitting layer interposed therebetween;
a circuit element layer disposed between the display element layer and the base substrate and comprising a pixel circuit electrically connected to the pixel electrode; and
a color control layer disposed on the display element layer and having a light transmittance corresponding to yellow that is higher than a light transmittance corresponding to blue.

14. The display device according to claim 13, wherein the color control layer comprises amorphous silicon.

15. The display device according to claim 13, wherein the color control layer has a maximum value of light transmittance in a wavelength range between 570 nm and 590 nm.

16. The display device according to claim 13, wherein the color control layer has a minimum value of light reflectance in a wavelength range between 570 nm and 590 nm.

17. The display device according to claim 13, wherein in a state where a voltage between the pixel electrode and the opposing electrode is lower than a driving voltage of the light-emitting layer, a reflectance of light corresponding to blue is higher than a reflectance of light corresponding to yellow in the display element layer.

18. The display device of claim 13, wherein, in a state where a voltage between the pixel electrode and the opposing electrode is lower than a driving voltage of the light-emitting layer, a reflectance of light corresponding to green is higher than a reflectance of light corresponding to red in the display element layer.

19. An electronic device comprising a display device, wherein the display device comprises:
a base substrate;
a display element layer disposed on the base substrate and comprsing a light-emitting layer, a pixel electrode disposed between the light-emitting layer and the base substrate, an opposing electrode facing the pixel electrode with the light-emitting layer interposed therebetween, and a pixel defining layer surrounding the pixel electrode and not overlapping a portion of the pixel electrode;
a circuit element layer disposed between the display element layer and the base substrate and comprising a pixel circuit electrically connected to the pixel electrode; and
a color control layer disposed on the display element layer and comprising amorphous silicon,
wherein the pixel electrode comprises a first upper surface that is recessed with respect to the light-emitting layer and not overlapping the pixel defining layer and a second upper surface extending from the first upper surface and overlapping the pixel defining layer, and
wherein the color control layer overlaps the second upper surface.

20. The electronic device of claim 19, further comprising:
a processor configured to execute an application to transfer image data signals to the display device;
a memory in which data information for executing the application is stored; and
a power module configured to supply power to the display device, the processor, and the memory,
wherein the display device is configured to output image information based on the image data signals.
